(19) United States
(12) Patent Application Publication
(10) Pub. No.: US 2026/0189229 A1
(43) Pub. Date: Jul. 2, 2026

(54) METHODS AND SYSTEMS FOR REDUCING NOISE DURING SWITCH STATE TRANSITIONS

(71) Applicant: Murata Manufacturing Co., Ltd., Nagaokakyo-shi (JP)

(72) Inventor: Bryan Lee Hash, Lake Zurich, IL (US)

(21) Appl. No.: 19/547,551

(22) Filed: Feb. 23, 2026

Related U.S. Application Data
(63) Continuation-in-part of application No. 18/829,165, filed on Sep. 9, 2024.
(60) Provisional application No. 63/951,404, filed on Dec. 30, 2025.

(51) Int. Cl. H03K 17/16

(52) U.S. Cl. CPC H03K 17/16

(57) ABSTRACT

Techniques are provided for reducing cross-coupled noise. For example, a method includes coupling an input node to a ground by a primary shunt switch in a closed state, decoupling an output node from the input node by a primary through switch in an open state, switching the primary shunt switch from the closed state to an open state to decouple the input node from the ground, switching the primary through switch from the open state to a closed state to couple the output node to the input node and provide a circuit path for an RF signal from an RF source to a load, and switching an ancillary switch from an open state to a closed state to couple the ancillary switch across one of the primary switches to reduce cross-coupled noise. Additional systems, devices, circuits, and methods are also provided.

### CROSS-REFERENCE TO RELATED APPLICATIONS

This patent application is a continuation-in-part of U.S. Patent Application No. 18/829,165 filed September 9, 2024 entitled “Methods and Systems for Reducing Noise During Switch State Transitions” which is hereby incorporated by reference in its entirety.

This patent application claims priority to and the benefit of U.S. Provisional Patent Application No. 63/951,404 filed December 30, 2025 entitled “Methods and Systems for Reducing Noise During Switch State Transitions” which is incorporated herein by reference in its entirety.

### TECHNICAL FIELD

This disclosure relates generally to switching circuits and, more specifically, to techniques for reducing noise induced during switch state transitions.

### BACKGROUND

When an electronic switch transitions from one stable state to another (e.g., off to on or on to off) to selectively couple a source to a load, the switch may introduce a voltage modulation at the load and generate a significant amount of noise distributed over a large frequency range (e.g., from DC up to 100 MHz or more). The noise is the result of the source and load not seeing a constant impedance during the switch transition. The peak amplitude of the noise is a function of how fast the switch changes state, which will follow a Gaussian distribution in time at each frequency where the noise is present. As the amount of time for the switch to change state is reduced, the peak of the noise will increase.

For switches used to pass radio frequency (RF) signals, this noise can be mixed up to the RF frequency of the RF signal passing from an RF source to an RF load such as an RF antenna, resulting in a broadband second order intercept point (IP2) tone being generated as an intermodulation product of the noise and the RF signal. This IP2 tone can result in an RF receiver being unable to receive the RF signal passed from the RF antenna (e.g., the IP2 tone may cause the RF receiver to experience a desense in which the IP2 tone is high enough to block desired frequencies of the RF signal). Such noise can also impact the error vector magnitude (EVM) of the transmit or receive path of a digital RF transceiver while the switch is changing state.

Although some noise reduction may be achieved by increasing the switch time and thereby distributing the noise over a longer time period with decreased amplitude, such an approach limits the maximum switch rate of the switch and may be impractical in many applications.

### SUMMARY

Various techniques are provided for reducing cross-coupled noise induced by switch transitions in RF circuits. In one embodiment, a method includes coupling an input node to a ground by a primary shunt switch in a closed state, wherein the input node is configured to receive an RF signal from an RF source; decoupling an output node from the input node by a primary through switch in an open state, wherein the output node is configured to pass the RF signal to a load; switching the primary shunt switch from the closed state to an open state to decouple the input node from the ground; switching the primary through switch from the open state to a closed state to couple the output node to the input node and provide a circuit path for the RF signal from the RF source to the load; and switching an ancillary switch from an open state to a closed state to couple the ancillary switch across one of the primary switches to reduce cross-coupled noise induced by the switching of the one of the primary switches before the RF signal is received by the input node.

In another embodiment, a switching circuit includes an input node configured to receive an RF signal from an RF source; an output node configured to pass the RF signal to a load; a primary shunt switch configured to selectively shunt the input node to a ground; a primary through switch configured to selectively couple the input node to the output node to provide a circuit path for the RF signal from the RF source to the load; and an ancillary switch configured to be selectively coupled across the one of the primary switches to reduce cross-coupled noise induced by a switching of the one of the primary switches before the RF signal is received by the input node.

In another embodiment, a method includes receiving, by a resistor network, one or more primary control signals; providing, by the resistor network, a plurality of delayed control signals to cause a plurality of switches to operate with staggered delays in relation to each other in response thereto, the providing comprising: providing, by a first resistor of the resistor network, a first one of the delayed control signals, and providing, by a second resistor of the resistor network, a second one of the delayed control signals; transitioning a first one of the switches in response to the first delayed control signal after a first delay relative to the one or more control signals, wherein the first delay is determined by at least the first resistor and a first capacitance of the first switch; and transitioning a second one of the switches in response to the second delayed control signal after a second delay relative to the one or more control signals, wherein the second delay is determined by at least the second resistor and a second capacitance of the second switch.

In another embodiment, a system includes a resistor network configured to receive one or more primary control signals and provide a plurality of delayed control signals to cause a plurality of switches to operate with staggered delays in relation to each other in response thereto, the resistor network comprising: a first resistor configured to provide a first one of the delayed control signals, and a second resistor configured to provide a second one of the delayed control signals; a first one of the switches configured to transition in response to the first delayed control signal after a first delay relative to the one or more control signals, wherein the first delay is determined by at least the first resistor and a first capacitance of the first switch; and a second one of the switches configured to transition in response to the second delayed control signal after a second delay relative to the one or more control signals, wherein the second delay is determined by at least the second resistor and a second capacitance of the second switch.

Additional techniques are provided to protect ancillary switches while an RF signal is received by a switching circuit. For example, in another embodiment, a method includes receiving an RF signal at an input node coupled to an output node through at least a primary switch, an impedance circuit, and an ancillary switch; switching the ancillary switch from an open state to a closed state while the primary switch is in an open state; dissipating a first portion of the RF signal by the impedance circuit while the ancillary switch is in the closed state; passing a second portion of the RF signal by the ancillary switch in the closed state while the primary switch is in the open state; switching the primary switch from the open state to a closed state; and passing a majority RF signal by the primary switch in the closed state to the output node.

In another embodiment, a switching circuit includes an input node configured to receive an RF signal; an output node, wherein the input node is coupled to the output node through at least a primary switch, an ancillary switch, and an impedance circuit; the impedance circuit configured to dissipate a first portion of the RF signal while the ancillary switch is in a closed state; the ancillary switch configured to: switch from an open state to the closed state while the primary switch remains in an open state, and while in the closed state, pass a second portion of the RF signal while the primary switch is in an open state; and the primary switch configured to: switch from the open state to a closed state, and while in the closed state, pass a majority of the RF signal to the output node.

Additional embodiments are also disclosed.

### BRIEF DESCRIPTION OF THE DRAWINGS

FIG. 1 illustrates a switching circuit and related components in accordance with an embodiment of the disclosure.

FIG. 2 illustrates a process of transitioning a switching circuit from an open state to a closed state in accordance with an embodiment of the disclosure.

FIG. 3 illustrates a process of transitioning a switching circuit from a closed state to an open state in accordance with an embodiment of the disclosure.

FIG. 4 illustrates a timing diagram associated with transitioning a switching circuit in accordance with an embodiment of the disclosure.

FIG. 5A illustrates voltage modulation associated with operating a primary shunt switch and a primary through switch without operating an ancillary switch in accordance with an embodiment of the disclosure.

FIG. 5B illustrates noise associated with operating a primary shunt switch and a primary through switch without operating an ancillary switch in accordance with an embodiment of the disclosure.

FIG. 6A illustrates voltage modulation associated with operating a primary shunt switch, a primary through switch, and an ancillary shunt switch in accordance with an embodiment of the disclosure.

FIG. 6B illustrates noise associated with operating a primary shunt switch, a primary through switch, and an ancillary shunt switch in accordance with an embodiment of the disclosure.

FIG. 7A illustrates voltage modulation associated with operating a primary shunt switch, a primary through switch, and an ancillary through switch in accordance with an embodiment of the disclosure.

FIG. 7B illustrates noise associated with operating a primary shunt switch, a primary through switch, and an ancillary through switch in accordance with an embodiment of the disclosure.

FIG. 8A illustrates voltage modulation associated with operating a primary shunt switch, a primary through switch, an ancillary shunt switch, and an ancillary through switch in accordance with an embodiment of the disclosure.

FIG. 8B illustrates noise associated with operating a primary shunt switch, a primary through switch, an ancillary shunt switch, and an ancillary through switch in accordance with an embodiment of the disclosure.

FIGS. 9-12 illustrate circuits including resistor networks providing control signals to switches of switching circuits in accordance with embodiments of the disclosure.

FIG. 13 illustrates a process of providing control signals in accordance with an embodiment of the disclosure.

FIG. 14 illustrates a timing diagram of a staggered switch sequence using a single primary control signal in accordance with an embodiment of the disclosure.

FIG. 15 illustrates a timing diagram of a staggered switch sequence using a plurality of primary control signals in accordance with an embodiment of the disclosure.

FIG. 16-18 illustrate switching circuits with impedance elements to protect ancillary switches in accordance with embodiments of the disclosure.

FIG. 19 illustrates a process of operating switching circuits with impedance elements to protect ancillary switches in accordance with an embodiment of the disclosure.

FIG. 20 illustrates a process of operating a switching circuit with an impedance element to protect an ancillary switch in accordance with an embodiment of the disclosure.

FIGS. 21-22 illustrate timing diagrams for a switching circuit with an impedance element to protect an ancillary switch in accordance with an embodiment of the disclosure.

Embodiments of the present disclosure and their advantages are best understood by referring to the detailed description that follows. It should be appreciated that like reference numerals are used to identify like elements illustrated in one or more of the figures.

### DETAILED DESCRIPTION

In accordance with various embodiments disclosed herein, techniques are provided to reduce noise generated by an electronic RF switching circuit while it transitions from an open state to a closed state and vice versa. In some embodiments, one or more matched loads (e.g., ancillary loads) are coupled (e.g., connected) across various portions of a switching circuit before it begins transitioning to a new state (e.g., from off to on or from on to off) and then decoupled (e.g., disconnected) after the transition to the new state is completed.

By adding these loads across portions of the switching circuit while it transitions between states, the impedance at input and output nodes of the switching circuit during the transitions may be better controlled, thereby reducing switching generated noise that can result in added noise on adjacent active RF circuit paths.

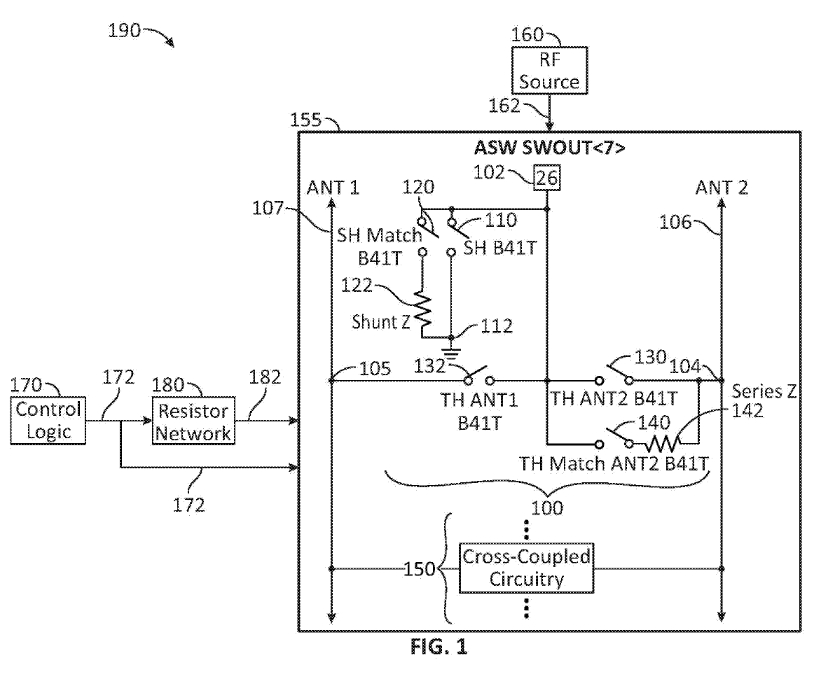

Turning now to the drawings, FIG. 1 illustrates a switching circuit 100 and related components in accordance with an embodiment of the disclosure. Switching circuit 100 operates to selectively route an RF signal 162 received from an RF source 160 at an input node 102 to one or more loads such as antennas 106 and 107 at output nodes 104 and 105 through various switches.

Switching circuit 100 includes a primary shunt switch 110 that selectively operates to shunt input node 102 to a ground 112 to isolate input node 102 when RF signal 162 is not present. Primary shunt switch 110 also selectively operates to disconnect input node 102 from ground 112 when RF signal 162 is present. Switching circuit 100 also includes a primary though switch 130 that selectively operates to disconnect input node 102 from output node 104 to isolate output node 104 when RF signal 162 is not present. Primary through switch 130 also selectively operates to connect input node 102 to output node 104 to pass RF signal 162 when present.

Switching circuit 100 also includes an additional primary though switch 132 that selectively operates to disconnect input node 102 from output node 105 when RF signal 162 is not present and to connect input node 102 to output node 105 when RF signal 162 is present. In some embodiments, primary through switches 130 and 132 may be operated independently of each other and/or synchronously with each other (e.g., RF signal 162 may be routed to one, both, or neither of output nodes 104 and 105 in various embodiments).

Switching circuit 100 also includes an ancillary shunt switch 120 and an ancillary load 122 (e.g., a resistor and/or other load exhibiting an appropriate impedance) that may be selectively coupled across primary shunt switch 110. Switching circuit 100 also includes an ancillary through switch 140 and an ancillary load 142 (e.g., a resistor and/or other load exhibiting an appropriate impedance) that may be selectively coupled across primary through switch 130.

In some embodiments, an additional ancillary through switch (not shown) and additional associated load (not shown) may be coupled across additional primary through switch 132. The various aspects of primary through switch 130 and ancillary through switch 140 described herein may be similarly applied to additional primary through switch 132 and its associated additional ancillary through switch and additional associated load.

Additional cross-coupled circuitry 150 such as additional switches, routing circuits, and/or other circuitry may be coupled between output nodes 104/105 and therefore also between antennas 106/107. In this regard, cross-coupled circuitry 150 may pass noise induced at output node 104 (e.g., by the switching of primary shunt switch 110 and/or primary through switch 130) to output node 105, and may similarly pass noise induced at output node 105 (e.g., by the switching of primary shunt switch 110 and/or primary through switch 132) to output node 104. As further discussed herein, the operation of ancillary shunt switch 120 and/or ancillary through switch 140 and their associated ancillary loads 122 and 142, respectively, may reduce such noise.

For convenience of illustration, the combination of switching circuit 100, antennas 106 and 107, and cross-coupled circuitry 150 are collectively shown in a block 155 in communication with various other components. For example, block 155, RF source 160, control logic 170, and resistor network 180 may collectively provide an RF system 190 as shown.

Control logic 170 provides one or more primary control signals 172 that may be used to control the various primary switches 110/130/132, ancillary switches 120/140, and/or others of switching circuit 100 and/or other circuits (e.g., portions of cross-coupled circuitry 150) as appropriate. In some embodiments, control logic 170 may be implemented by, for example, one or more processors, microcontrollers, finite state machines, sequential logic components, and/or other hardware and/or software as appropriate.

In some embodiments, primary control signals 172 may be provided directly to the various switches of switching circuit 100 (e.g., directly to block 155) and/or through a resistor network 180 which converts the primary control signals 172 to delayed control signals 182 further discussed herein.

The various benefits of ancillary switches 120/140 and ancillary loads 122/142 may be further appreciated by considering the operation of switching circuit 100 in a conventional manner without ancillary switches 120/140 and without ancillary loads 122/142. For example, in such a conventional implementation, while RF signal 162 is not present, primary shunt switch 110 may be closed and primary through switch 130 may be open. In this state, RF source 160 sees a low impedance at input node 102, and antenna 106 sees a high impedance at output node 104. If primary shunt switch 110 opens and primary through switch 130 closes simultaneously with each other, then input node 102 will transition from the low impedance to an intermediate impedance, and output node 104 will transition from the high impedance to the intermediate impedance. In this regard, input node 102 and output node 104 will both exhibit a moderate change in impedance.

Similarly, if primary shunt switch 110 closes and primary through switch 130 opens simultaneously with each other, then input node 102 will transition from the intermediate impedance to the low impedance, and output node 104 will transition from the intermediate impedance to the high impedance. In this case, input node 102 and output node 104 will both exhibit a moderate change in impedance again.

However, if primary shunt switch 110 and primary through switch 130 do not transition simultaneously with each other, then the impedance at input node 102 and/or output node 104 may exhibit a substantially larger change in impedance, resulting in an increased voltage modulation at output nodes 104 and 105 and associated increased cross-coupled noise at output nodes 104 and 105.

For example, if primary shunt switch 110 transitions from a closed state to an open state while primary through switch 130 temporarily remains in an open state before it transitions to a closed state (e.g., both primary shunt switch 110 and primary through switch 130 are both temporarily open at the same time), then input node 102 may exhibit an impedance change from a low impedance to a temporary high impedance. Input node 102 may then exhibit a further impedance change from the high impedance to the intermediate impedance after primary through switch 130 transitions from the open state to the closed state. This drastic change in impedance at input node 102 (e.g., from low to high to intermediate) may result in increased noise being induced in switching circuit 100 and one or more voltage modulations at antenna 106 and/or 107 (e.g., through cross-coupled circuitry 150) that appear as noise at antenna 106 and/or antenna 107.

As another example, if primary through switch 130 transitions from an open state to a closed state while primary shunt switch 110 temporarily remains in a closed state before it transitions to an open state (e.g., both primary shunt switch 110 and primary through switch 130 are both temporarily closed at the same time), then output node 104 may exhibit an impedance change from a high impedance to a temporary low impedance. Output node 104 may then exhibit a further impedance change from the low impedance to the intermediate impedance after primary shunt switch 110 transitions from the closed state to the open state. This drastic change in impedance at output node 104 (e.g., from high to low to intermediate) may result in increased noise being induced in switching circuit 100 and one or more voltage modulations at antenna 106 and/or 107 (e.g., through cross-coupled circuitry 150) that appear as noise at antenna 106 and/or antenna 107.

In some cases, the voltage modulations and increased noise associated with the above-described impedance changes may be reduced by increasing the switch times of primary shunt switch 110 and primary through switch 130 and thereby distributing the noise over a longer time period with decreased amplitude. However, such an approach limits the maximum switch rate of switching circuit 100 and may be impractical in many applications as discussed.

In accordance with various embodiments of the present disclosure, the above-noted impedance changes may be reduced by adding to switching circuit 100 various combinations of ancillary shunt switch 120, ancillary load 122, ancillary through switch 140, and ancillary load 142. As a result, the voltage modulation and noise induced by the operation of switching circuit 100 may be reduced.

Ancillary shunt switch 120 and ancillary through switches 140 may be operated to reduce the impedance changes appearing at input node 102 and output node 104 while switching circuit 100 transitions from open to closed states and vice versa. In some embodiments, ancillary loads 122 and 142 may be provided to further reduce such impedance changes and dissipate cross-coupled noise.

In various embodiments, primary shunt switch 110, primary through switch 130, and primary through switch 132 may be sized to pass RF signal 162 (e.g., a high power signal for transmission from antenna 106 and/or 107) while closed. In contrast, ancillary shunt switch 120 and ancillary through switch 140 may be substantially smaller and therefore not used to pass RF signal 162. As a result, ancillary shunt switch 120 and ancillary through switch 140 may exhibit reduced noise and faster switching times than primary shunt switch 110, primary through switch 130, and primary through switch 132. In some embodiment, the reduced size of ancillary shunt switch 120 and ancillary through switch 140 and the addition of ancillary loads 122 and 142 may reduce any impact to the overall insertion loss of switching circuit 100 resulting from their inclusion. In other embodiments, if it is desired for ancillary shunt switch 120 and/or ancillary through switch 140 to pass RF signal 162, their sizes may be adjusted as appropriate.

Any desired resistance values may be selected for each of ancillary loads 122 and 142 (e.g., 1 ohm, 25 ohms, 50 ohms, and/or others) as appropriate to exhibit desired impedances at input node 102 and output node 104 under various operating conditions. Although single ancillary loads 122 and 142 illustrated, other embodiments are also contemplated. For example, in some embodiments, additional ancillary loads may be provided that are connected through appropriate switches to sequentially increase the impedance connected through ancillary shunt switch 120 and/or ancillary through switch 140 (e.g., stepped impedance changes from 12 ohms, to 25 ohms, to 50 ohms, and the reverse) and/or to adjust the impedances at input node 102 and output node 104 for different operating conditions.

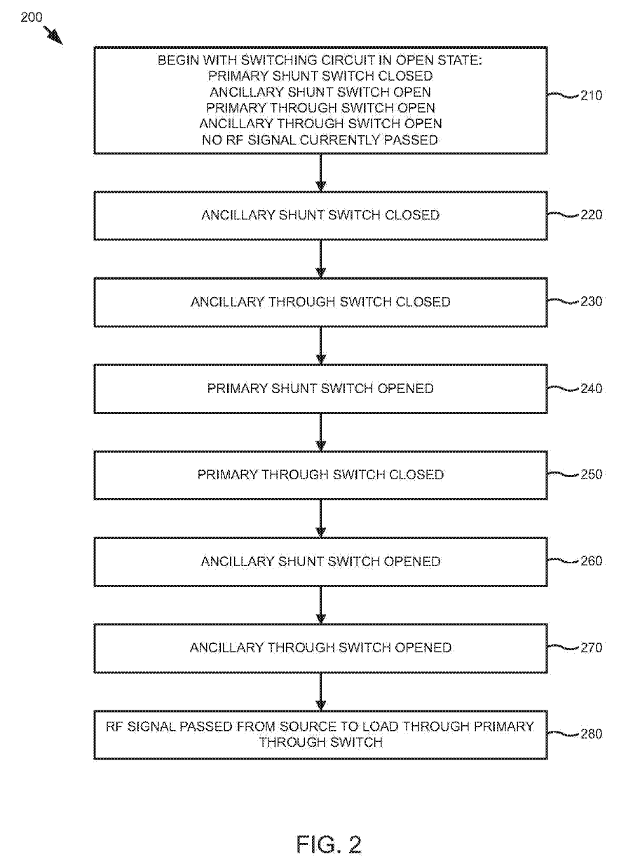

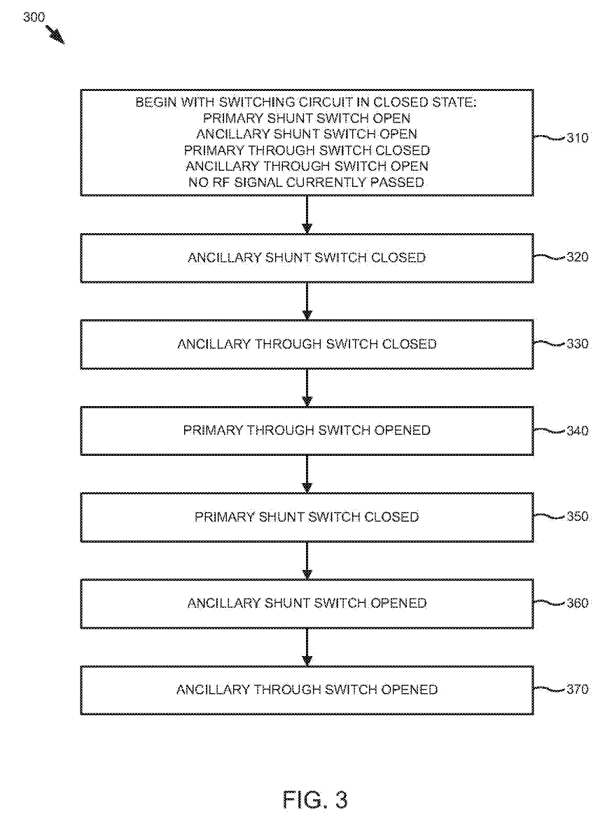

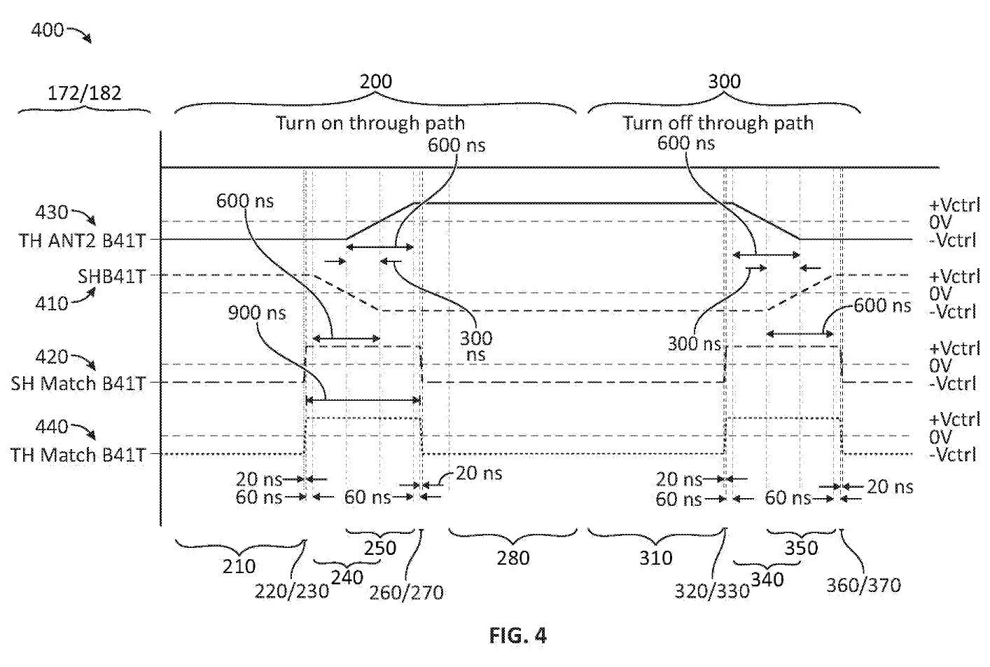

The operation of switching circuit 100 will now be described in relation to the processes illustrated in FIGS. 2 and 3 and the timing diagram of FIG. 4. FIG. 2 illustrates a process 200 of transitioning switching circuit 100 from an open state to a closed state in accordance with an embodiment of the disclosure. The various blocks illustrated in FIG. 2 also correspond to associated time periods in timing diagram 400 of FIG. 4. Although various particular time periods are illustrated in FIG. 4 and discussed herein, these are merely for purposes of example and other time periods may be used as appropriate. Moreover, the order of the various operations and control signals may be adjusted in various embodiments as appropriate.

As shown in FIG. 4, control signals 410, 420, 430, and 440 are illustrated (e.g., collectively provided by one or more of primary control signals 172 and/or delayed control signals 182) which are used to adjust the operation of primary shunt switch 110, primary through switch 130, ancillary shunt switch 120, and ancillary through switch 140, respectively.

In block 210, switching circuit 100 is in an open state wherein primary shunt switch 110 is closed, ancillary shunt switch 120 is open, primary through switch 130 is open, ancillary through switch 140 is open, and no RF signal 162 is currently being passed by RF source 160. For example, the open state of block 210 may result from a previous completion of process 300 of FIG. 3 further described herein.

In block 210, input node 102 exhibits low impedance resulting from closed primary shunt switch 110 connecting input node 102 to ground 112. Also in block 210, output node 104 exhibits high impedance resulting from open primary through switch 130 and open ancillary through switch 140.

Over the course of blocks 220 to 270, switching circuit 100 transitions from the open state to the closed state. In block 220, control signal 420 operates to transition ancillary shunt switch 120 from open to closed. Input node 102 remains at low impedance while closed primary shunt switch 110 continues to connect input node 102 to ground 112. Also in block 220, output node 104 remains at high impedance while primary through switch 130 and ancillary through switch 140 both remain open.

In block 230, control signal 440 operates to transition ancillary through switch 140 from open to closed which causes output node 104 to transition to intermediate impedance as a result of ancillary load 142 now being connected between output node 104 and input node 102. Also in block 230, input node 102 remains at low impedance while closed primary shunt switch 110 continues to connect input node 102 to ground 112.

Although blocks 220 and 230 are illustrated sequentially, blocks 220 and 230 may be performed in any order or simultaneously. For example, as shown in FIG. 4, control signals 420 and 440 are illustrated as transitioning simultaneously over 20 nanosecond time periods in some embodiments.

In block 240, control signal 410 operates to transition primary shunt switch 110 from closed to open. As a result, input node 102 transitions from low impedance to intermediate impedance due to the connection of ancillary load 122 between input node 102 and ground 112 by previously closed ancillary shunt switch 120. Also in block 240, output node 104 remains at intermediate impedance while previously closed ancillary through switch 140 continues to connect ancillary load 142 between output node 104 and input node 102.

As shown in FIG. 4, the operation of block 240 may begin 60 nanoseconds after blocks 220 and 230 have completed. As also shown in FIG. 4, this transition of primary shunt switch 110 may extend over a time period of 600 nanoseconds.

Thus, following block 240, input node 102 and output node 104 will both exhibit intermediate impedance. In particular, input node 102 remains at intermediate impedance while ancillary load 122 remains connected between input node 102 and ground 112 through closed ancillary shunt switch 120. Similarly, output node 104 remains at intermediate impedance while ancillary load 142 remains connected between output node 104 and input node 102 through closed ancillary through switch 140.

It will be appreciated that this approach removes the drastic swing between low and high impedance values at input node 102 and output node 104 that would otherwise be caused by non-simultaneous switching in conventional implementations as previously discussed. In particular, input node 102 has transitioned from low impedance to intermediate impedance, and output node 104 has transitioned from high impedance to intermediate impedance.

In block 250, control signal 430 operates to transition primary through switch 130 from open to closed. Input node 102 remains at intermediate impedance while ancillary load 122 remains connected between input node 102 and ground 112 through closed ancillary shunt switch 120. Output node 104 remains at intermediate impedance while output node 104 is connected to input node 102 through closed primary through switch 130. Although ancillary load 142 is now bypassed by closed primary through switch 130, intermediate impedance is maintained by the connection between input node 102 and output node 104 through closed primary through switch 130.

As shown in FIG. 4, the operation of block 250 may begin 300 nanoseconds after block 240 begins. As also shown in FIG. 4, this transition of primary through switch 130 may extend over a time period of 600 nanoseconds. Thus, it will be appreciated that blocks 240 and 250 may overlap as shown in FIG. 4.

In block 260, control signal 440 operates to transition ancillary shunt switch 120 from closed to open. Although ancillary load 122 is now disconnected by open ancillary shunt switch 120, input node 102 and output node 104 both remain at intermediate impedance through their connection between primary through switch 130.

In block 270, control signal 420 operates to transition ancillary through switch 140 from closed to open. Although ancillary load 142 is now disconnected by open ancillary through switch 140, input node 102 and output node 104 both remain at the intermediate impedance while they remain connected through closed primary through switch 130.

Although blocks 260 and 270 are illustrated sequentially, blocks 260 and 270 may be performed in any order or simultaneously.

Following block 270, switching circuit 100 will have fully transitioned from the open state to the closed state. Accordingly, in block 280, RF source 160 provides RF signal 162 to switching circuit 100 which passes RF signal 162 from input node 102 to output node 104 by the closed primary through switch 130.

FIG. 3 illustrates a process 300 of transitioning switching circuit 100 from a closed state to an open state in accordance with an embodiment of the disclosure. The various blocks illustrated in FIG. 3 also correspond to associated time periods in timing diagram 400 of FIG. 4. Although various particular time periods are illustrated in FIG. 4 and discussed herein, these are merely for purposes of example and other time periods may be used as appropriate. Moreover, the order of the various operations and control signals may be adjusted in various embodiments as appropriate.

In block 310, switching circuit 100 is in a closed open state wherein primary shunt switch 110 is open, ancillary shunt switch 120 is open, primary through switch 130 is closed, ancillary through switch 140 is open, and no RF signal 162 is currently being passed by RF source 160. For example, the closed state of block 310 may result from a previous completion of process 200 of FIG. 2 further described herein. In this example, the RF signal 162 previously passed in block 280 of FIG. 2 will have been interrupted (e.g., between the time periods corresponding to blocks 280 and 310 illustrated in FIG. 4) and no longer passed by RF source 160 in block 310.

In block 310, input node 102 and output node 104 both exhibit intermediate impedance resulting from closed primary through switch 130 connecting input node 102 to output node 104.

Over the course of blocks 320 to 370, switching circuit 100 transitions from the closed state to the open state. In block 320, control signal 420 operates to transition ancillary shunt switch 120 from open to closed which causes ancillary load 122 to be connected between input node 102 and ground 112. Input node 102 and output node 104 both remain at intermediate impedance by the connection between input node 102 and output node 104 through closed primary through switch 130.

In block 330, control signal 440 operates to transition ancillary through switch 140 from open to closed which causes ancillary load 142 to be connected between input node 102 and output node 104. Input node 102 and output node 104 both remain at intermediate impedance by the connection between input node 102 and output node 104 through closed primary through switch 130.

Although blocks 320 and 330 are illustrated sequentially, blocks 320 and 330 may be performed in any order or simultaneously.

In block 340, control signal 410 operates to transition primary through switch 130 from closed to open. Input node 102 and output node 104 both remain at intermediate impedance by the connection between input node 102 and output node 104 through closed ancillary through switch 140.

As shown in FIG. 4, the operation of block 240 may begin 60 nanoseconds after blocks 220 and 230 have completed. As also shown in FIG. 4, this transition of primary shunt switch 110 may extend over a time period of 600 nanoseconds.

Thus, following block 340, input node 102 and output node 104 will both exhibit intermediate impedance. In particular, input node 102 remains at intermediate impedance while ancillary load 122 remains connected between input node 102 and ground 112 through closed ancillary shunt switch 120. Similarly, output node 104 remains at intermediate impedance while ancillary load 142 remains connected between output node 104 and input node 102 through closed ancillary through switch 140 and ancillary load 142.

It will be appreciated that this approach removes the drastic swing between low and high impedance values at input node 102 and output node 104 that would otherwise be caused by non-simultaneous switching in conventional implementations as previously discussed. In particular, input node 102 and output node 104 have both maintained intermediate impedance even though primary shunt switch 110 and primary through switch 130 have not switched simultaneously.

In block 350, control signal 430 operates to transition primary shunt switch 110 from open to closed. Input node 102 transitions to low impedance as it is pulled to ground 112 by the closing of primary shunt switch 110, thus bypassing ancillary load 122. Output node 104 remains at intermediate impedance while output node 104 is connected to input node 102 through closed ancillary through switch 140 and ancillary load 142.

As shown in FIG. 4, the operation of block 350 may begin 300 nanoseconds after block 340 begins. As also shown in FIG. 4, this transition of primary shunt switch 110 may extend over a time period of 600 nanoseconds. Thus, it will be appreciated that blocks 340 and 350 may overlap as shown in FIG. 4.

In block 360, control signal 440 operates to transition ancillary shunt switch 120 from closed to open. Input node 102 remains at low impedance as it is pulled to ground 112 by the previously closed primary shunt switch 110. Output node 104 remains at intermediate impedance while output node 104 is connected to input node 102 through closed ancillary through switch 140 and ancillary load 142.

In block 370, control signal 420 operates to transition ancillary through switch 140 from closed to open which causes output node 104 to transition to high impedance. Input node 102 remains at low impedance as it is pulled to ground 112 by the previously closed primary shunt switch 110.

Although blocks 360 and 370 are illustrated sequentially, blocks 360 and 370 may be performed in any order or simultaneously.

Following block 370, switching circuit 100 will have fully transitioned from the closed state to the open state.

In view of the above discussion of FIGS. 2 and 3, it will be appreciated that the operation of ancillary shunt switch 120 and ancillary through switch 140 with their associated ancillary loads 122 and 142, respectively, reduce the impedance swing experienced by input node 102 and output node 104, even when primary shunt switch 110 and primary through switch 130 do not switch simultaneously. As a result, cross-coupled noise exhibited at output nodes 104 and 105 may be reduced.

Moreover, the above discussed techniques improve over conventional approaches that rely on intentionally increasing switching times. For example, the relatively small sizes of ancillary shunt switch 120 and ancillary through switch 140 permit them to switch rapidly (e.g., faster than primary shunt switch 110 and primary through switch 130) and therefore introduce no increase in switching times.

In various embodiments, any additional minor impedance changes introduced during process 200 of FIG. 2 may be negligible (e.g., in block 240, output node 104 may experience a small impedance change as a bypass of ancillary load 122 is removed by the opening of primary shunt switch 110; in block 250, output node 104 may experience a small impedance change as ancillary load 122 is bypassed by the closing of primary through switch 130; in block 260, input node 102 and output node 104 may experience small impedance changes as ancillary load 122 is disconnected by the opening of ancillary shunt switch 120).

Similarly, in various embodiments, any minor impedance changes introduced during process 300 of FIG. 3 may also be negligible (e.g., in block 320, input node 102 and output node 104 may experience small impedance changes as ancillary load 122 is connected by the closing of ancillary shunt switch 120; in block 340, input node and output node 104 may experience small impedance changes as a bypass of ancillary load 142 is removed by the opening of primary through switch 130; in block 350, output node 104 may experience a small impedance change as ancillary load 122 is bypassed by the closing of primary shunt switch 110).

For example, these minor impedance changes during processes 200 and 300 may be negligible due to the small sizes of ancillary shunt switch 120, ancillary load 122, ancillary through switch 140, and ancillary load 142. Moreover, even if small impedance changes are introduced, the processes 200 and 300 will still avoid the large impedance changes (e.g., low to high and/or high to low) associated with prior techniques previously discussed.

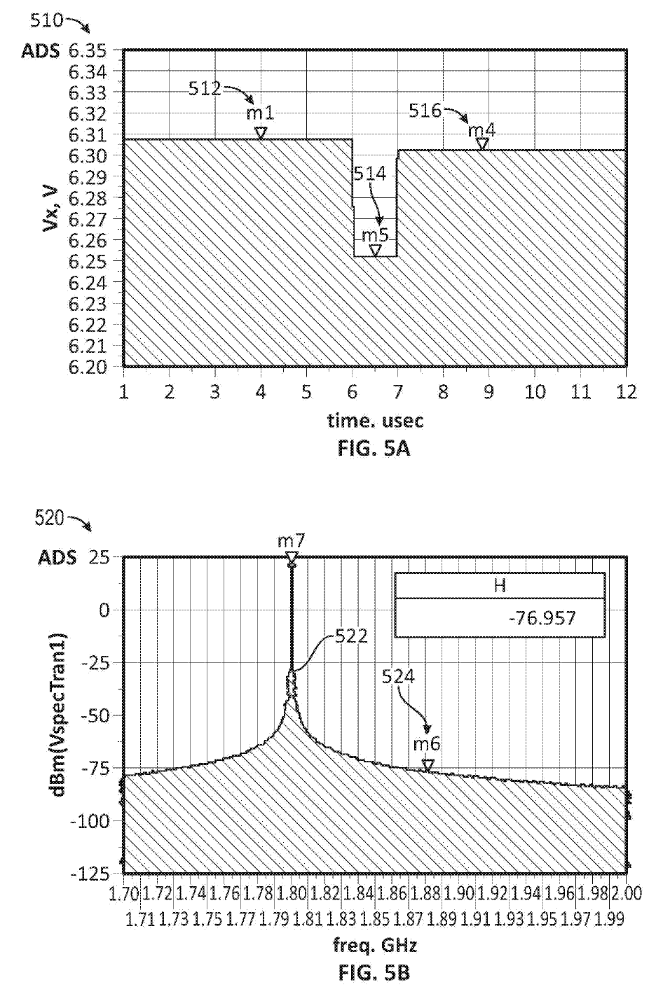

Various benefits of the present disclosure can be further appreciated by a review of test results provided in FIGS. 5A through 8B.

FIGS. 5A and 5B illustrate test results obtained by operating switching circuit 100 without ancillary shunt switch 120, ancillary load 122, ancillary through switch 140, and ancillary load 142.

In FIG. 5A, plot 510 identifies the voltage at output node 105 during an open state 512, during a state transition 514, and during a closed state 516 after the transition. As shown, output node 105 exhibits a voltage modulation as primary shunt switch 110 and primary through switch 130 are operated to transition 514 from the open state 512 to the closed state 516.

In FIG. 5B, plot 520 identifies cross-coupled noise introduced at antenna 107 (e.g., connected to output node 105) by the voltage modulation shown in plot 510. Plot 520 identifies a noise peak 522 and a power spectral density 524 of the noise. FIG. 5B further identifies a ratio H of the noise to an RF carrier signal of antenna 107.

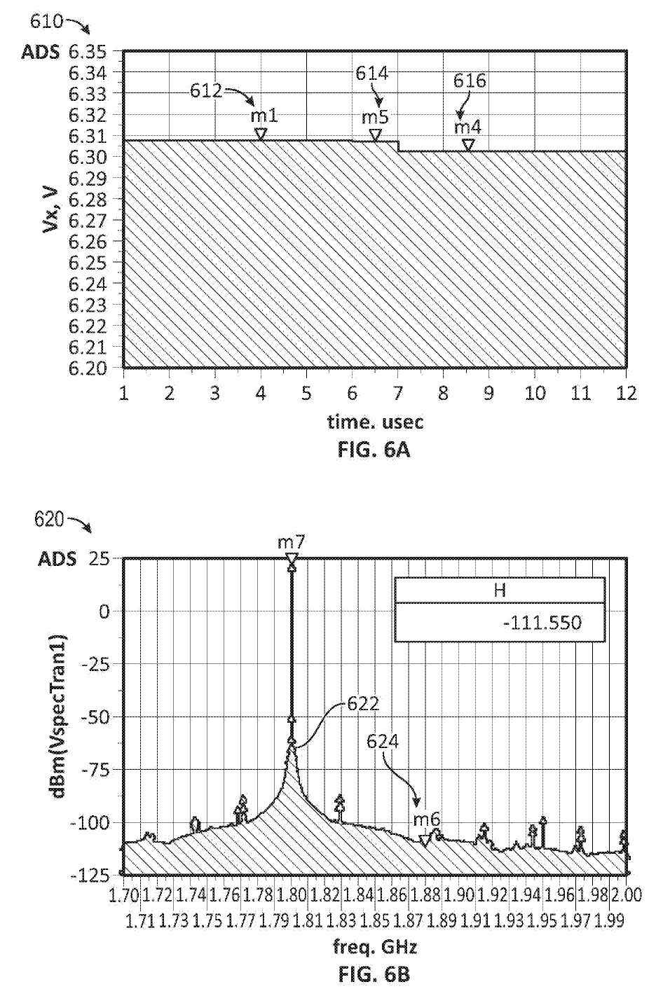

FIGS. 6A and 6B illustrate test results obtained by operating switching circuit 100 with ancillary shunt switch 120 and ancillary load 122 (e.g., 1 ohm in this example), but without ancillary through switch 140 and ancillary load 142.

In FIG. 6A, plot 610 identifies the voltage at output node 105 during an open state 612, during a state transition 614, and during a closed state 616 after the transition. As shown, output node 105 exhibits a voltage modulation as primary shunt switch 110, ancillary shunt switch 120, ancillary load 122, and primary through switch 130 are operated to transition 614 from the open state 612 to the closed state 616. It will be appreciated that the voltage modulation shown in plot 610 is reduced in comparison with plot 510 as a result of the operation of ancillary shunt switch 120.

In FIG. 6B, plot 620 identifies cross-coupled noise introduced at antenna 107 by the voltage modulation shown in plot 610. Plot 620 identifies a noise peak 622 and a power spectral density 624 of the noise. Noise peak 622 of plot 620 is reduced by 35dB in comparison with noise peak 522 of plot 520 as a result of the operation of ancillary shunt switch 120 and ancillary load 122. Ratio H of plot 620 is reduced in comparison with plot 510 as a result of the operation of ancillary shunt switch 120 and ancillary load 122.

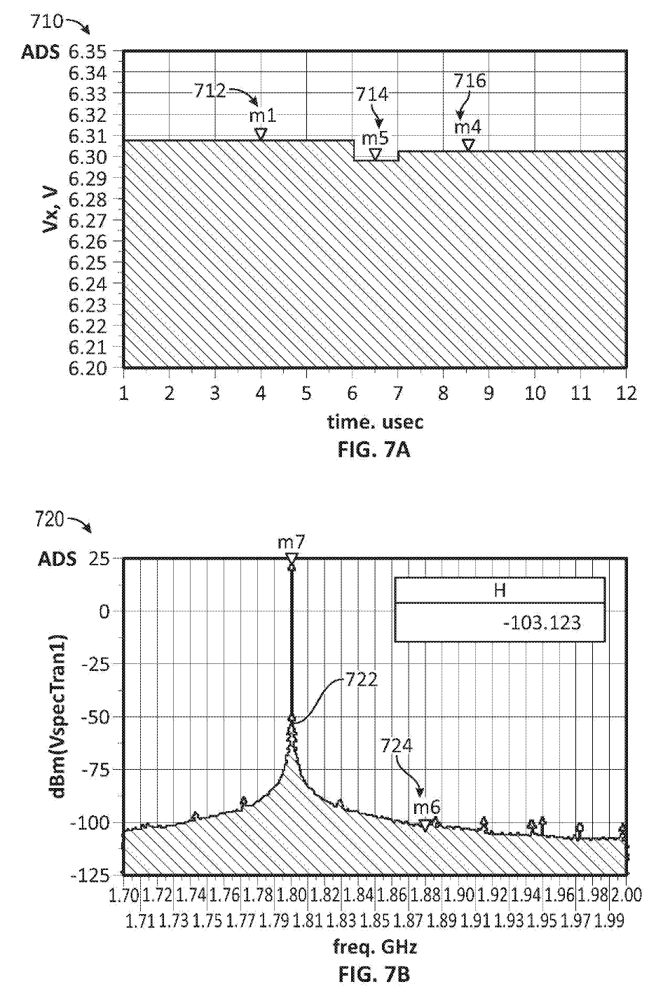

FIGS. 7A and 7B illustrate test results obtained by operating switching circuit 100 with ancillary through switch 140 and ancillary load 142 (e.g., 1 ohm in this example), but without ancillary shunt switch 120 and ancillary load 122 (e.g., 1 ohm in this example).

In FIG. 7A, plot 710 identifies the voltage at output node 105 during an open state 712, during a state transition 714, and during a closed state 716 after the transition. As shown, output node 105 exhibits a voltage modulation as primary shunt switch 110, primary through switch 130, ancillary through switch 140, and ancillary load 142 are operated to transition 714 from the open state 712 to the closed state 716. It will be appreciated that the voltage modulation shown in plot 710 is reduced in comparison with plot 510 as a result of the operation of ancillary through switch 140 and ancillary load 142.

In FIG. 7B, plot 720 identifies cross-coupled noise introduced at antenna 107 by the voltage modulation shown in plot 710. Plot 720 identifies a noise peak 722 and a power spectral density 724 of the noise. Noise peak 722 of plot 720 is reduced by 29dB in comparison with noise peak 522 of plot 520 as a result of the operation of ancillary through switch 140 and ancillary load 142. Ratio H of plot 720 is reduced in comparison with plot 510 as a result of the operation of ancillary through switch 140 and ancillary load 142.

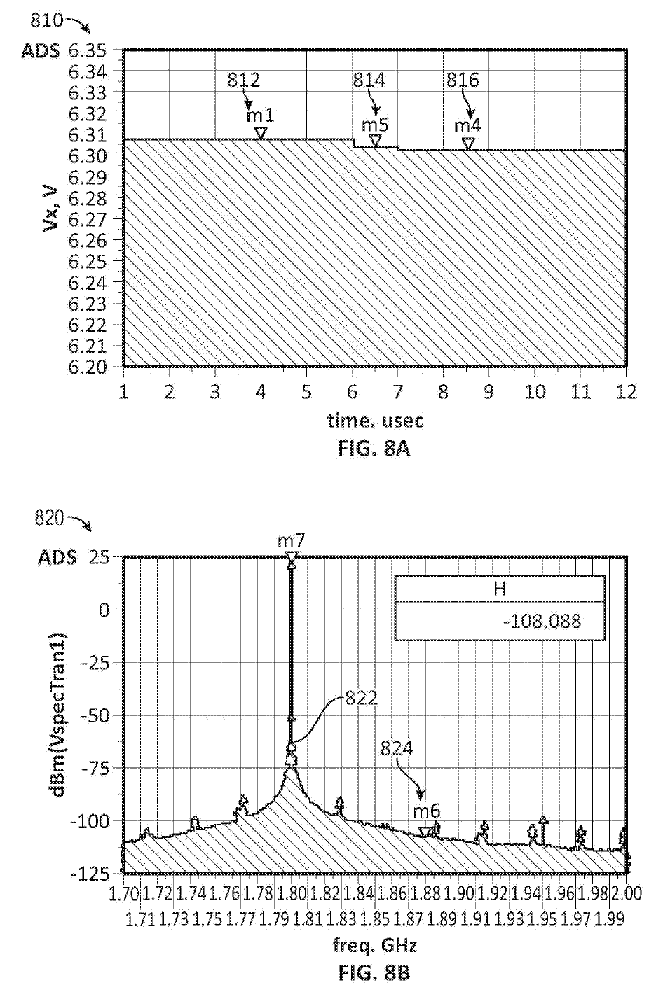

FIGS. 8A and 8B illustrate test results obtained by operating switching circuit 100 with ancillary shunt switch 120, ancillary load 122 (e.g., 25 ohms in this example), ancillary through switch 140, and ancillary load 142 (e.g., 25 ohms in this example).

In FIG. 8A, plot 810 identifies the voltage at output node 105 during an open state 812, during a state transition 814, and during a closed state 816 after the transition. As shown, output node 105 exhibits a voltage modulation as primary shunt switch 110, ancillary shunt switch 120, ancillary load 122, primary through switch 130, ancillary through switch 140, and ancillary load 142 are operated to transition 814 from the open state 812 to the closed state 816. It will be appreciated that the voltage modulation shown in plot 810 is reduced in comparison with plot 510 as a result of the operation of ancillary shunt switch 120, ancillary load 122, ancillary through switch 140, and ancillary load 142.

In FIG. 8B, plot 820 identifies cross-coupled noise introduced at antenna 107 by the voltage modulation shown in plot 810. Plot 820 identifies a noise peak 822 and a power spectral density 824 of the noise. Noise peak 822 of plot 820 is reduced by 32dB in comparison with noise peak 522 of plot 520 as a result of the operation of ancillary shunt switch 120, ancillary load 122, ancillary through switch 140, and ancillary load 142. Ratio H of plot 720 is reduced in comparison with plot 510 as a result of the operation of ancillary shunt switch 120, ancillary load 122, ancillary through switch 140, and ancillary load 142.

Thus, it will be appreciated that the use of various combinations of ancillary shunt switch 120, ancillary load 122, ancillary through switch 140, and/or ancillary load 142 may reduce voltage modulation and associated cross-coupled noise induced by the operation of switching circuit 100. For example, including only ancillary shunt switch 120 and ancillary load 122, only ancillary through switch 140 and ancillary load 142, and/or all such components provides measurable improvements and reductions in switch-induced voltage modulation and cross-coupled noise.

Accordingly, although the processes of FIGS. 2 and 3 have been described as using all of ancillary shunt switch 120, ancillary load 122, ancillary through switch 140, and ancillary load 142, it is contemplated that any desired combination of such components (e.g., fewer or greater components as appropriate) may be used in accordance with the present disclosure.

The generation of various control signals used to operating switching circuit 100 will now be discussed. As previously shown and described in FIG. 1, control signals 172 and/or 182 may be used to operate the various switches discussed herein. In some embodiments, primary control signals 172 may be used which are entirely generated by control logic 170. For example, control logic 170 may generate primary control signals 172 with appropriate timing to control the various switches as desired. In some embodiments, delayed control signals 182 may be provided by resistor network 180 that exhibit staggered delays in relation to each other as a result of time constants determined by various resistors of resistor network 180, capacitances of the controlled switches (e.g., control gate capacitances of switched transistors implementing the switches), and/or other factors. In some embodiments, various combinations of primary control signals 172 and delayed control signals 182 may be used to control the switches.

As discussed, in some embodiments, a single primary control signal 172 may be provided to resistor network 180 which provides one or more delayed control signals 182 in response thereto. In some embodiments, the delayed control signals 182 delay the switching of the various controlled switches relative to the primary control signal 172 by RC time constants associated with the particular resistances of resistors of resistor network 180 and the particular capacitances of the various controlled switches (e.g., control gate capacitances of transistors implementing the switches). In other embodiments, multiple primary control signals 172 may be provided to resistor network 180 which similarly provides one or more delayed control signals 182 in response thereto.

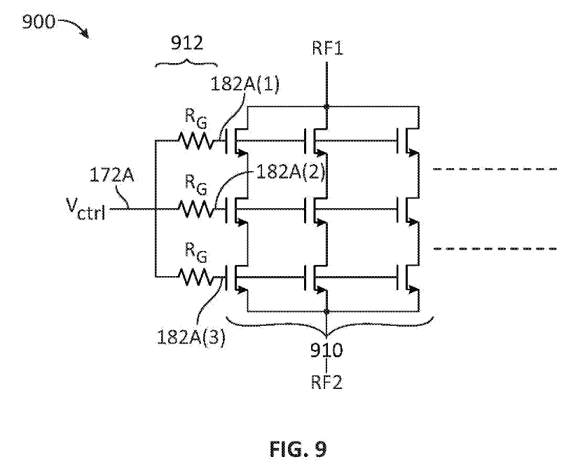

Various circuits 900, 1000, 1100, and 1200 are illustrated in FIGS. 9-12 further described herein. For example, in FIGS. 9-12, various resistors are provided to implement at least a portion of resistor network 180. In addition, groups of switches (e.g., transistors) are provided (e.g., arranged in one or more rows and columns), wherein each group may be used to implement a corresponding switch of switching circuit 100. For example, in some embodiments, multiple switches (e.g., multiple transistors) provided in a group of switches in FIGS. 9-12 may be used to implement a single one of the switches of switching circuit 100.

In some embodiments, in circuits 1000, 1100 and 1200, dedicated portions of the circuits are not required to implement ancillary switches 120 and 140 and ancillary impedances 122 and 142. For example, by delaying the on and off transitions of portions of primary shunt switch 110 and/or primary through switch 130 (e.g., subsets of the various switches illustrated in circuits 1000, 1100, and 1200 used to implement primary shunt switch 110 and/or primary through switch 130), ancillary switches 120 and 140 may be effectively implemented. Advantageously, in such embodiments, circuits 1000 and 1100 may be implemented without adjustments to control logic 170.

In FIGS. 9-12, although various numbers of resistors and switches are illustrated, their particular arrangement and numbers are not limiting. Other implementations are also contemplated.

In some embodiments, the large groups of switches 910, 1020, 1120, and 1220 (e.g., including parallel columns of transistors) in circuits 900, 1000, 1100, and 1200 may be used, for example, to implement primary shunt switch 110, primary through switch 130, or primary through switch 132 in order to pass RF signal 162 (e.g., a high power signal). In some embodiments, the numbers of switches in these groups may be determined by a maximum allowed on resistance and an amount of RF power passed therethrough.

In some embodiments, the smaller groups of switches 1010/1110/1210 and 1030/1130/1230 may be used, for example to implement ancillary shunt switch 120 or ancillary though switch 140 which are not used to pass high power signals.

In FIG. 9, circuit 900 includes switches 910 and resistors 912. Switches 910 (e.g., a switch group) are implemented as transistors in multiple rows and columns with the control gates of each row connected together and are used to collectively implement one or more of the switches of switching circuit 100. Resistors 912 are arranged in a column and are used to implement at least a portion of resistor network 180.

As shown, resistors 912 receive a primary control signal 172A from control logic 170 and provide delayed control signals 182A(1)-(3) in response thereto which operate switches 910. The timing of the switching performed by switches 910 in response to delayed control signals 182A(1)-(3) may be determined by the RC time constants associated with the various combinations of resistors 912 and switches 910. For example, if resistors 912 exhibit the same resistance (e.g., R_{G} in this example), and switches 910 exhibit the same capacitance, then switches 910 will exhibit the same switching delays relative to primary control signal 172A in response to delayed control signals 182A(1)-(3). In other embodiments, adjusting the resistances of resistors 912 and/or the capacitances of switches 910 (e.g., by sizing the transistors of switches 910 appropriately) may result in different switching delays at different switches 910. As a result, switches 910 may be operated at the same time and/or in a staggered manner in response to a single primary control signal 172A to implement a desired switching sequence, for example, to implement the various switch operations of the present disclosure.

In some embodiments, the resistances of resistors 912 may be increased to adjust the RC time constants and therefore increase the total switching time for one or more switches implemented by circuit 900. In some embodiments, these changes in resistance may be selected to restrain the total switching time to be within a maximum allowable range and therefore maintain a desired switch rate for switching circuit 100.

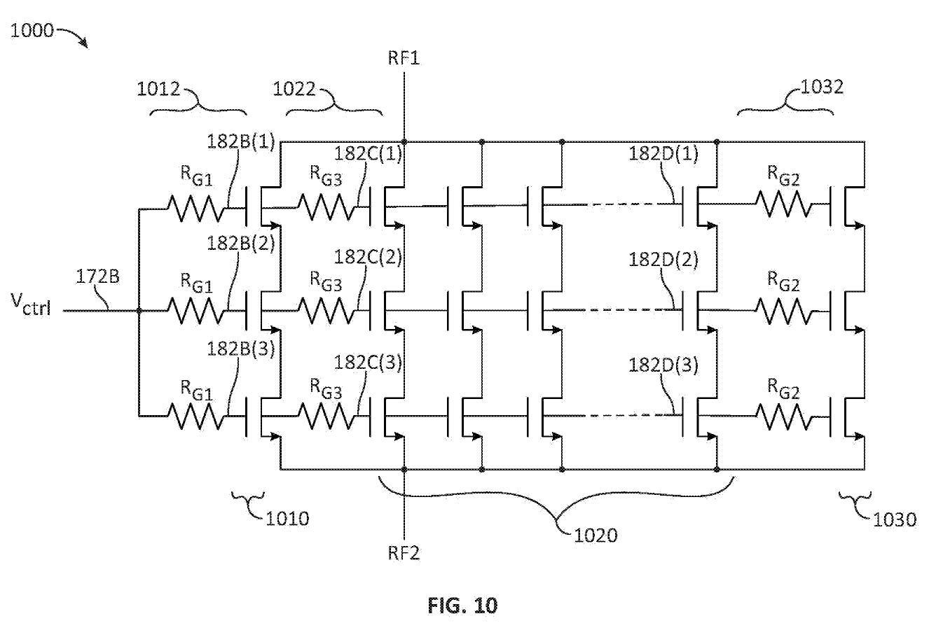

In FIG. 10, circuit 1000 includes: switches 1010, 1020, and 1030; and resistors 1012, 1022, and 1032 which are used to implement at least a portion of resistor network 180. Switches 1010 are implemented as transistors in multiple rows and a single column with the control gates of each row connected to respective ones of resistors 1012. Switches 1020 are implemented as transistors in multiple rows and multiple columns with the control gates of each row connected together in series with respective ones of resistors 1022, switches 1010, and resistors 1012. Switches 1030 are implemented as transistors in multiple rows and a single column with the control gates of each row connected to respective ones of resistors 1032 that are connected in series with respective control gates of switches 1020, resistors 1022, control gates of switches 1010, and resistors 1012.

Other embodiments are also contemplated. For example, in some embodiments, switch 1010 and/or 1030 may be implemented with multiple columns of transistors, each connected to resistors 1012 and 1032, respectively (e.g., in a manner similar to switch 1020 implemented with multiple columns of transistors, each connected to resistors 1022). In this example, the total number of columns of transistors in switches 1010 and 1030 may be significantly less than the number of columns of transistors in switch 1020 (e.g., as the size of switches 1010 and 1030 may be smaller than switch 1020).

As shown, resistors 1012 receive a primary control signal 172B from control logic 170 and provide delayed control signals 182B(1)-(3) in response thereto which operate switches 1010. The timing of the switching performed by switches 1010 in response to delayed control signals 182B(1)-(3) may be determined by the RC time constants associated with the various combinations of resistors 1012 and switches 1010.

Resistors 1022 receive delayed control signals 182B(1)-(3) and provide delayed control signals 182C(1)-(3) in response thereto which operate switches 1020. The timing of the switching performed by switches 1020 in response to delayed control signals 182C(1)-(3) may be determined by the RC time constants associated with the various combinations of resistors 1012 and 1022 and switches 1010 and 1020.

Resistors 1032 receive delayed control signals 182C(1)-(3) and provide delayed control signals 182D(1)-(3) in response thereto which operate switches 1030. The timing of the switching performed by switches 1030 in response to delayed control signals 182D(1)-(3) may be determined by the RC time constants associated with the various combinations of resistors 1012, 1022, and 1032 and switches 1010, 1020, and 1030.

Thus, by adjusting the resistances of resistors 1012, 1022, and 1032 and adjusting the capacitances of switches 1010, 1020, and 1030 the switching times of the switches in response to delayed control signals 182B(1)-(3), 182C(1)-(3), and 182C(1)-(3) may be adjusted to implement a desired switching sequence in response to a single primary control signal 172B.

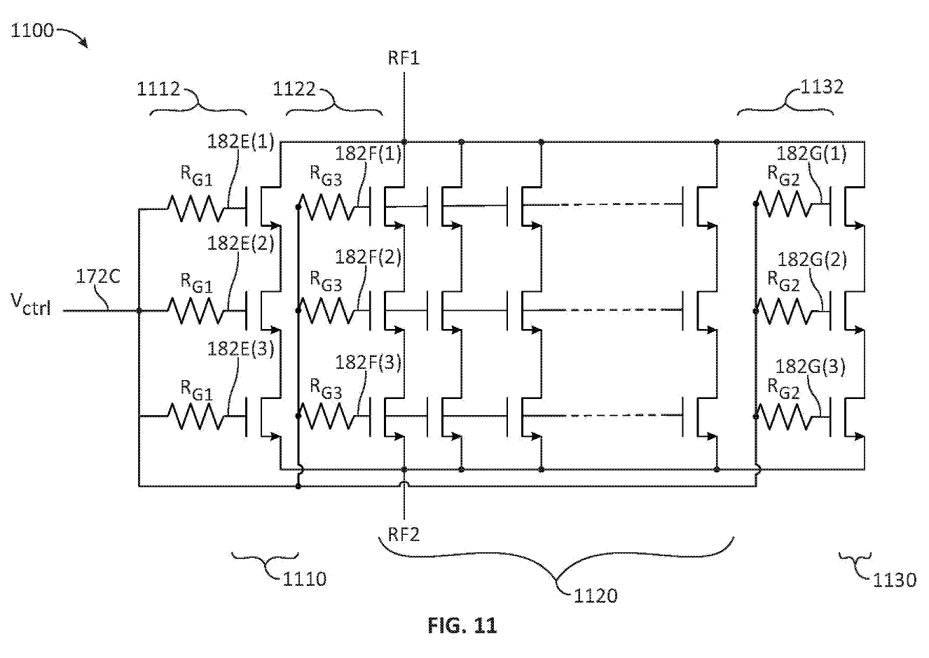

In FIG. 11, circuit 1100 includes: switches 1110, 1120, and 1130; and resistors 1112, 1122, and 1132 which are used to implement at least a portion of resistor network 180. Switches 1110 are implemented as transistors in multiple rows and a single column with the control gates of each row connected to respective ones of resistors 1112. Switches 1120 are implemented as transistors in multiple rows and multiple columns with the control gates of each row connected together in series with respective ones of resistors 1122. Switches 1130 are implemented as transistors in multiple rows and a single column with the control gates of each row connected to respective ones of resistors 1132.

Other embodiments are also contemplated. For example, in some embodiments, switch 1110 and/or 1130 may be implemented with multiple columns of transistors, each connected to resistors 1112 and 1132, respectively (e.g., in a manner similar to switch 1120 implemented with multiple columns of transistors, each connected to resistors 1122). In this example, the total number of columns of transistors in switches 1110 and 1130 may be significantly less than the number of columns of transistors in switch 1120 (e.g., as the size of switches 1110 and 1130 may be smaller than switch 1120).

As shown, resistors 1112 receive a primary control signal 172C from control logic 170 and provide delayed control signals 182E(1)-(3) in response thereto which operate switches 1110. The timing of the switching performed by switches 1110 in response to delayed control signals 182E(1)-(3) may be determined by the RC time constants associated with the various combinations of resistors 1112 and switches 1110.

Resistors 1122 receive primary control signal 172C and provide delayed control signals 182F(1)-(3) in response thereto which operate switches 1120. The timing of the switching performed by switches 1120 in response to delayed control signals 182F(1)-(3) may be determined by the RC time constants associated with the various combinations of resistors 1122 and switches 1120.

Resistors 1132 receive primary control signal 172C and provide delayed control signals 182G(1)-(3) in response thereto which operate switches 1130. The timing of the switching performed by switches 1130 in response to delayed control signals 182G(1)-(3) may be determined by the RC time constants associated with the various combinations of resistors 1132 and switches 1130.

Thus, by adjusting the resistances of resistors 1112, 1122, and 1132 and adjusting the capacitances of switches 1110, 1120, and 1130 the switching times of the switches in response to delayed control signals 182E(1)-(3), 182F(1)-(3), and 182G(1)-(3) may be adjusted to implement a desired switching sequence in response to a single primary control signal 172C.

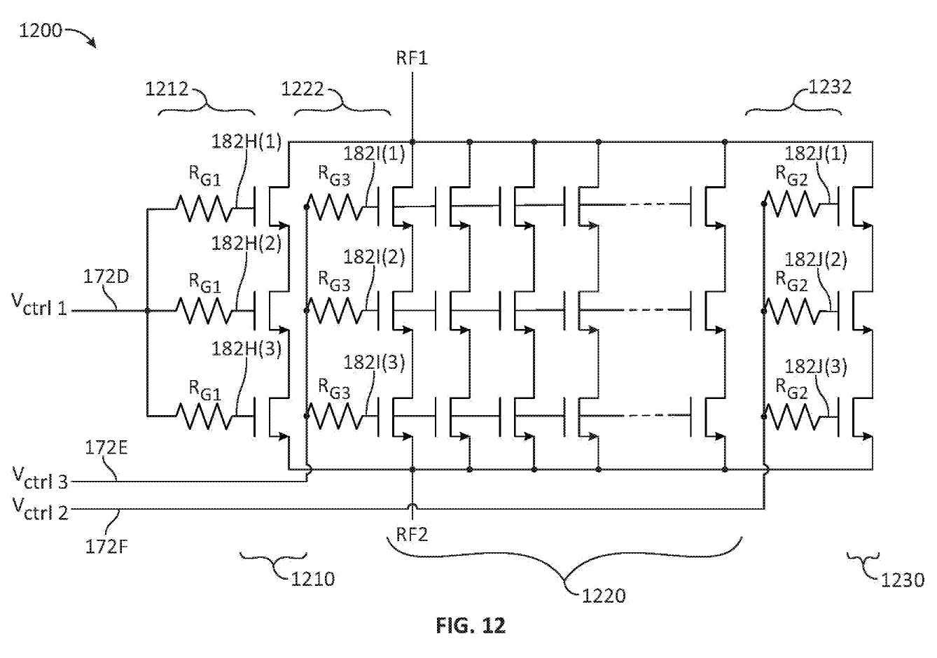

In FIG. 12, circuit 1200 includes: switches 1210, 1220, and 1230; and resistors 1212, 1222, and 1232 which are used to implement at least a portion of resistor network 180. Switches 1210 are implemented as transistors in multiple rows and a single column with the control gates of each row connected to respective ones of resistors 1212. Switches 1220 are implemented as transistors in multiple rows and multiple columns with the control gates of each row connected together in series with respective ones of resistors 1222. Switches 1230 are implemented as transistors in multiple rows and a single column with the control gates of each row connected to respective ones of resistors 1232.

Other embodiments are also contemplated. For example, in some embodiments, switch 1210 and/or 1230 may be implemented with multiple columns of transistors, each connected to resistors 1212 and 1232, respectively (e.g., in a manner similar to switch 1220 implemented with multiple columns of transistors, each connected to resistors 1222). In this example, the total number of columns of transistors in switches 1210 and 1230 may be significantly less than the number of columns of transistors in switch 1220 (e.g., as the size of switches 1210 and 1230 may be smaller than switch 1220).

As shown, resistors 1212 receive a primary control signal 172D from control logic 170 and provide delayed control signals 182H(1)-(3) in response thereto which operate switches 1210. The timing of the switching performed by switches 1210 in response to delayed control signals 182H(1)-(3) may be determined by the RC time constants associated with the various combinations of resistors 1212 and switches 1210.

Resistors 1222 receive a primary control signal 172E and provide delayed control signals 182I(1)-(3) in response thereto which operate switches 1220. The timing of the switching performed by switches 1220 in response to delayed control signals 182I(1)-(3) may be determined by the RC time constants associated with the various combinations of resistors 1222 and switches 1220.

Resistors 1232 receive a primary control signal 172F and provide delayed control signals 182J(1)-(3) in response thereto which operate switches 1230. The timing of the switching performed by switches 1230 in response to delayed control signals 182J(1)-(3) may be determined by the RC time constants associated with the various combinations of resistors 1232 and switches 1230.

Thus, by adjusting the resistances of resistors 1212, 1222, and 1232 and adjusting the capacitances of switches 1210, 1220, and 1230 the switching times of the switches in response to delayed control signals 182H(1)-(3), 182I(1)-(3), and 182J(1)-(3) may be adjusted to implement a desired switching sequence in response to multiple primary control signals 172D, 172E, and 172F. The timing may be further adjusted based on the relative delays of primary control signals 172D, 172E, and 172F to each other.

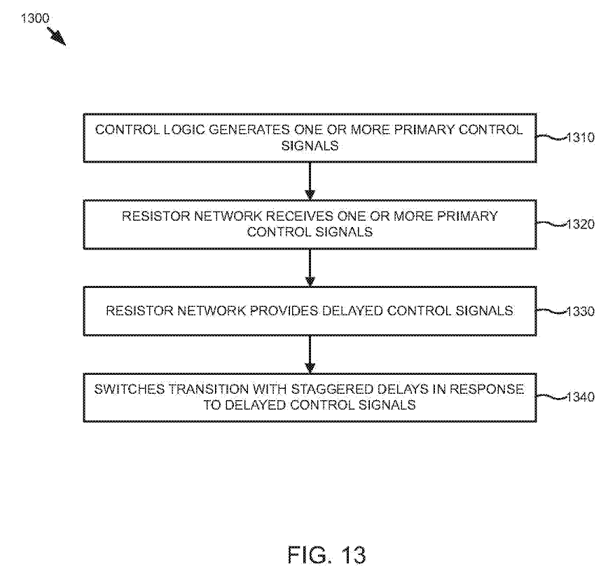

FIG. 13 illustrates a process of providing control signals to switches of any of circuits 900, 1000, 1100, and 1200 of FIGS. 9, 10, 11, and 12, respectively, in accordance with an embodiment of the disclosure.

In block 1310, control logic 170 provides one or more of primary control signals 172A-F as discussed.

In block 1320, the resistor networks implemented by the various resistors of circuits 900, 1000, 1100, and 1200 receive the primary control signals. For example, in circuit 900, resistors 912 receive primary control signal 172A as discussed. In circuit 1000, resistors 1012 receive primary control signal 172B as discussed. In circuit 1100, resistors 1112, 1122, and 1132 receive primary control signal 172C as discussed. In circuit 1200, resistors 1212 receive primary control signal 172D, resistors 1222 receive primary control signal 172E, and resistors 1232 receive primary control signal 172F as discussed.

In block 1330, the resistor networks implemented by the various resistors of circuits 900, 1000, 1100, and 1200 provide the various delayed control signals. For example, in circuit 900, resistors 912 provide delayed control signals 182A(1)-(3) as discussed. In circuit 1000, resistors 1012 provide delayed control signals 182B(1)-(3), resistors 1022 provide delayed control signals 182C(1)-(3), and resistors 1032 provide delayed control signals 182D(1)-(3), In circuit 1100, resistors 1112 provide delayed control signals 182E(1)-(3), resistors 1122 provide delayed control signals 182F(1)-(3), and resistors 1132 provide delayed control signals 182G(1)-(3) as discussed. In circuit 1200, resistors 1212 provide delayed control signals 182H(1)-(3), resistors 1222 provide delayed control signals 182I(1)-(3), and resistors 1232 provide delayed control signals 182J(1)-(3) as discussed.

In block 1340, the various switches of circuits 900, 1000, 1100, and 1200 transition with staggered delays in relation to each other in response to the delayed control signals. As discussed, these delays may be determined by the RC time constants associated with the various combinations of resistors and switches in circuits 900, 1000, 1100, and 1200. It will be appreciated that the switch transitions performed in block 1340 may be used to implement any of the switching performed by switching circuit 100 discussed herein.

For example, in circuit 900, switches 910 operate in response to delayed control signals 182A(1)-(3), In circuit 1000, switches 1010 operate in response to delayed control signals 182B(1)-(3), switches 1020 operate in response to delayed control signals 182C(1)-(3), and switches 1030 operate in response to delayed control signals 182D(1)-(3) as discussed. In circuit 1100, switches 1110 operate in response to delayed control signals 182E(1)-(3), switches 1120 operate in response to delayed control signals 182F(1)-(3), and switches 1130 operate in response to delayed control signals 182G(1)-(3) as discussed. In circuit 1200, switches 1210 operate in response to delayed control signals 182H(1)-(3), switches 1220 operate in response to delayed control signals 182I(1)-(3), and switches 1230 operate in response to delayed control signals 182J(1)-(3) as discussed.

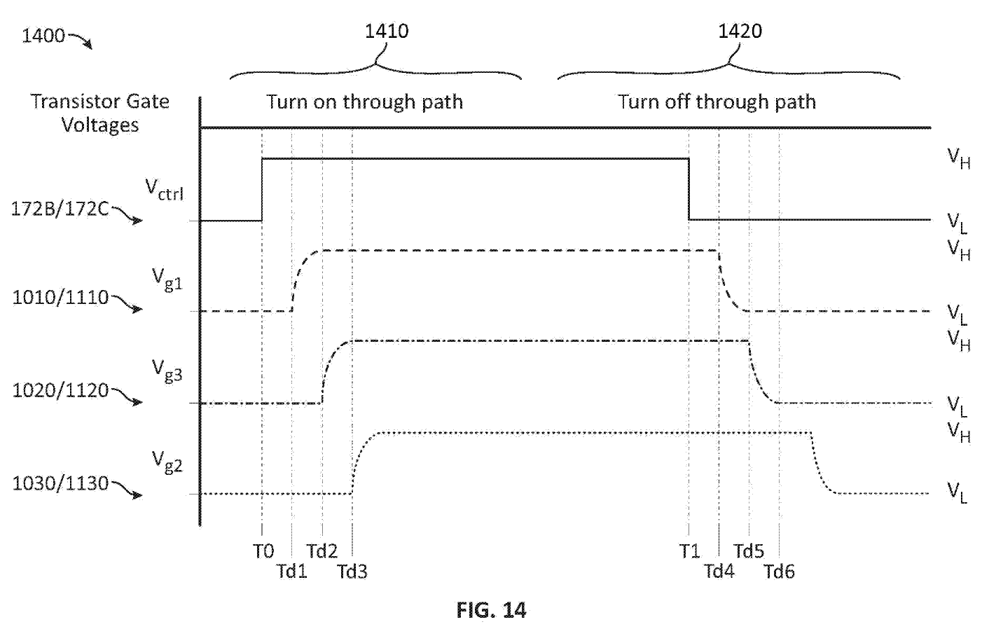

FIG. 14 illustrates a timing diagram 1400 of a staggered switch sequence using a single primary control signal in accordance with an embodiment of the disclosure. In particular, timing diagram 1400 identifies switching performed by circuits 1000 and 1100 of FIGS. 10 and 11 during process 1300 of FIG. 13 to transition switching circuit 100 between open and closed states in accordance with an embodiment of the disclosure.

In timing diagram 1400, switching circuit 100 transitions from an open state to a closed state over a time period 1410, and transitions from the closed state to the open state over a time period 1420. Primary control signals 172B/C are shown with their logic transitions occurring at T0 and T1. Gate voltages Vg1, Vg3, and Vg2 are also shown which correspond to the gate voltages of switches 1010/1120, 1020/1120, and 1030/1130 in response to delayed control signals 182B(1)-(3)/182E(1)-(3), 182C(1)-(3)/182F(1)-(3), and 182D(1)-(3)/182G(1)-(3), respectively.

As shown, the gate voltages begin rising and falling relative to each other as a result of the RC time constants associated with the various resistors and switches of circuits 1000 and 1100. In particular, gate voltages Vg1, Vg3, and Vg2 exhibit staggered delays relative to each other and primary control signals 172B/172C during time periods 1410 and 1420. As a result, the various switches of circuits 1000 and 1100 may operate in accordance with a desired switching sequence as discussed.

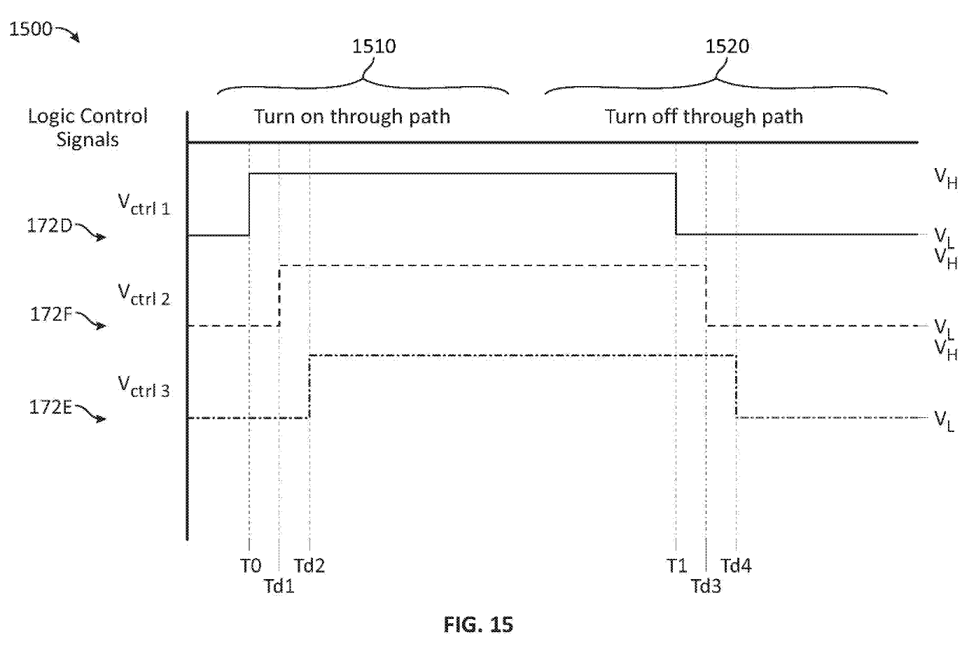

FIG. 15 illustrates a timing diagram 1500 of a staggered switch sequence using a plurality of primary control signals in accordance with an embodiment of the disclosure. In particular, timing diagram 1500 identifies switching performed by circuit 1200 of FIG. 12 during process 1300 of FIG. 13 to transition switching circuit 100 between open and closed states in accordance with an embodiment of the disclosure.

In timing diagram 1500, switching circuit 100 transitions from an open state to a closed state over a time period 1510, and transitions from the closed state to the open state over a time period 1520. Primary control signals 172D, 172E, and 172F are shown with their logic transitions occurring with staggered delays relative to each other. In this regard, control logic 170 itself may adjust the relative switching delays among switches 1210, 1220, and 1230 of circuit 1200.

As a result, the various switches 1210, 1220, and 1230 of circuit 1200 may operate in accordance with a desired switching sequence as discussed. Moreover, in some embodiments, the relative timing of gate voltages at switches 1210, 1220, and 1230 may be further adjusted and affected by the RC time constants associated with the various resistors and switches of circuit 1200.

In additional embodiments, one or more impedance circuits (e.g., each including one or more impedance elements) may be used to protect ancillary shunt switch 120 and ancillary through switch 140 when RF signal 162 (e.g., a high power RF signal) is present. For example, if RF signal 162 is received at input node 102 of switching circuit 100 while ancillary switches 120/140 are switched from open to closed states (e.g., hot switched) and while primary switches 110/130/132 are in open states, RF signal 162 may be passed by the closed ancillary switches 120/140.

However, as discussed, ancillary switches 120/140 may be sized smaller (e.g., to facilitate rapid switching) than primary switches 110/130/132. As a result, without sufficient protection, ancillary switches 120/140 may become damaged (e.g., shorted or permanently interrupted) if they are required to pass RF signal 162.

Therefore, in accordance with various embodiments, impedance circuits may be provided to dissipate a portion of RF signal 162 such that ancillary switches 120/140 only pass a reduced portion of RF signal 162 when they are in closed states. The impedance circuits may be sized to dissipate a sufficient portion of RF signal 162 such that the remaining portion passed by ancillary switches 120/140 is within normal operating levels (e.g., current levels that ancillary switches 120/140 are sized to pass without damage). As a result, ancillary switches 120/140 may be switched between open and closed states even while RF signal 162 is received by switching circuit 100 without risking damage to ancillary switches 120/140.

For example, in some embodiments, switching circuit 100 may be used to switch different antenna tuning elements in and out of a matching circuit while RF signal 162 is received at input node 102. By operating ancillary switches 120/140 as previously discussed but with additional impedance circuits provided, cross-coupled noise induced by the switching of primary switches 110/130/132 can be reduced even under hot switching conditions while RF signal 162 is received at input node 102. In addition, such operations limit the change in impedance across primary switches 110/130/132 as they transition, which reduces the amount of noise generated from such transitions.

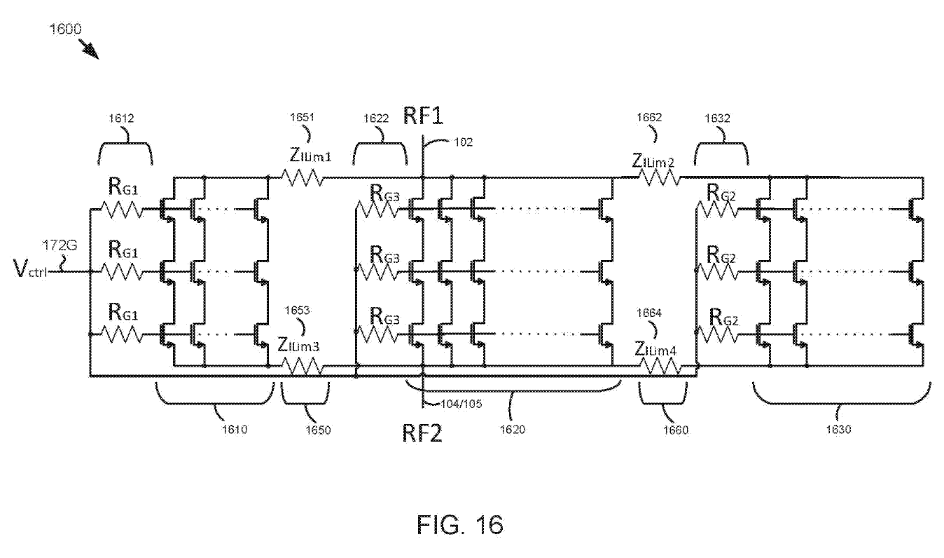

Various circuits 1600, 1700, and 1800 are illustrated in FIGS. 16, 17, and 18 further described herein. As similarly discussed with regard to FIGS. 9-12, various resistors are provided in FIGS. 16, 17, and 18 to implement at least a portion of resistor network 180. As also similarly discussed, groups of switches (e.g., transistors) are provided (e.g., arranged in one or more rows and columns), wherein each group may be used to implement a corresponding switch of switching circuit 100. For example, in some embodiments, multiple switches (e.g., multiple transistors) provided in a group of switches in FIGS. 16, 17, and 18 may be used to implement a single one of the switches of switching circuit 100.

In FIGS. 16, 17, and 18 although various numbers of resistors, switches, and impedance circuits are illustrated, their particular arrangement and numbers are not limiting. Other implementations are also contemplated. For example, although various switches of circuits 1600, 1700, and 1800 are illustrated in stacks of three serial transistors, other numbers of transistors may be used and may be determined, for example, by a maximum voltage swing of RF signal 162 and the maximum voltage each transistor in the stack can tolerate without breakdown.

In some embodiments, the groups of switches 1620, 1720, and 1820 in circuits 1600, 1700, and 1800 may be used, for example, to implement primary shunt switch 110, primary through switch 130, or primary through switch 132 to pass RF signal 162. In some embodiments, the numbers of switches in these groups may be determined by a maximum allowed on resistance and an amount of RF power passed therethrough.

In some embodiments, the other groups of switches 1610/1710/1810 and 1630/1730 may be used, for example to implement ancillary shunt switch 120 or ancillary though switch 140 which are not used to pass high power signals.

In FIG. 16, circuit 1600 connects input node 102 to output node 104/105 through switches 1610/1620/1630 and impedance circuits 1650/1660. Switches 1610/1620/1630 may be implemented as similarly discussed with regard to switches 1110/1120/1130 of FIG. 11. Circuit 1600 also includes resistors 1612, 1622, and 1632 which may be implemented as similarly discussed with regard to resistors 1112, 1122, and 1132 of FIG. 11.

Although switches 1610 and 1630 are illustrated in FIG. 16 with identical numbers of transistors, different numbers may be used for switches 1610 and 1630 (e.g., depending on different power handling requirements associated with the switching on and switching off of switch 1620).

Circuit 1600 also includes impedance circuits 1650 and 1660. As shown, impedance circuit 1650 includes an impedance element 1651 connected between input node 102 and switch 1610, and further includes an impedance element 1653 connected between switch 1610 and output node 104/105. Similarly, impedance circuit 1660 includes an impedance element 1662 connected between input node 102 and switch 1630, and further includes an impedance element 1664 connected between switch 1630 and output node 104/105.

As shown, switches 1610 and 1630 are each implemented by columns (e.g., sets) of transistors connected in series between the various impedance elements, and with each column of transistors connected in parallel with the other columns. Accordingly, it will be appreciated that all transistors of switches 1610 and 1630 share impedance elements 1651/1653 and 1662/1664, respectively.

Circuit 1600 may be operated in a similar manner as circuit 1100 of FIG. 11, but with additional features and capabilities provided by impedance circuits 1650/1660 as further discussed herein.

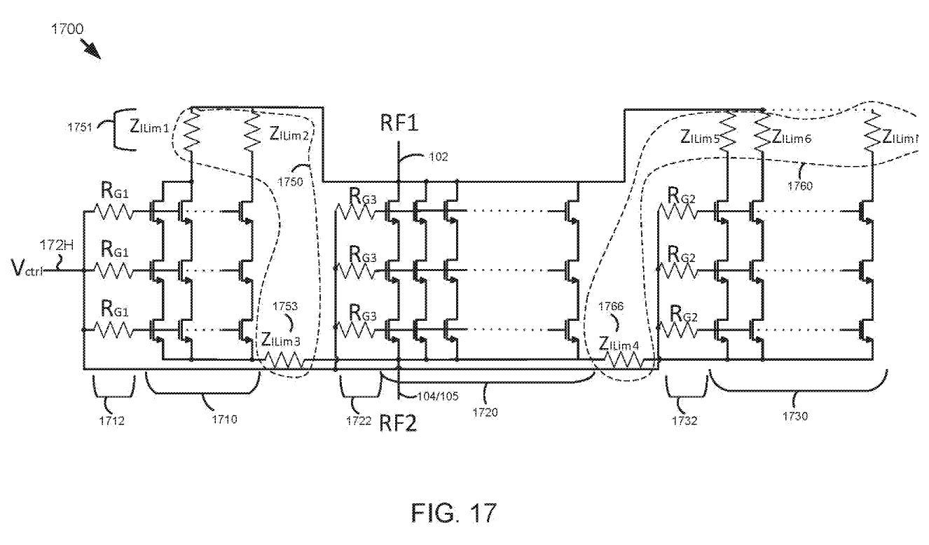

In FIG. 17, circuit 1700 connects input node 102 to output node 104/105 through switches 1710/1720/1730 and impedance circuits 1750/1760. Switches 1710/1720/1730 may be implemented as similarly discussed with regard to switches 1110/1120/1130 of FIG. 11. Circuit 1700 also includes resistors 1712, 1722, and 1732 which may be implemented as similarly discussed with regard to resistors 1112, 1122, and 1132 of FIG. 11.

Although switches 1710 and 1730 are illustrated in FIG. 17 with identical numbers of transistors, different numbers may be used for switches 1710 and 1730 (e.g., depending on different power handling requirements associated with the switching on and switching off of switch 1720).

Circuit 1700 also includes impedance circuits 1750 and 1760. As shown, impedance circuit 1750 includes multiple impedance elements 1751 connected between input node 102 and various columns of transistors of switch 1710, and an impedance element 1753 connected between switch 1710 and output node 104/105.

Similarly, impedance circuit 1760 includes multiple impedance elements 1765 connected between input node 102 and various columns of transistors of switch 1730, and an impedance element 1766 connected between switch 1730 and output node 104/105. Thus, it will be appreciated that various columns of transistors of switches 1710 and 1730 may have different impedance elements (e.g., multiple impedance elements 1751 and 1765) connecting them to input node 104, and shared impedance elements (e.g. impedance elements 1753 and 1766) connecting them to output node 104/105.

Circuit 1700 may be operated in a similar manner as circuit 1100 of FIG. 11, but with additional features and capabilities provided by impedance circuits 1750/1760 as further discussed herein.

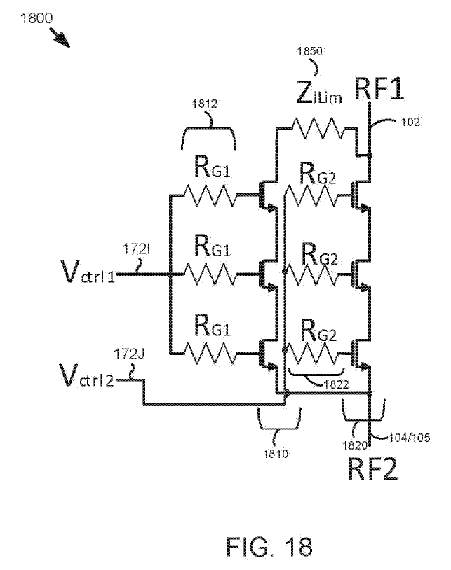

In FIG. 18, circuit 1800 connects input node 102 to output node 104/105 through switches 1810/1820 and impedance circuit 1850. Switches 1810/1820 may be implemented as similarly discussed with regard to switches 1210/1220 of FIG. 12. Circuit 1800 also includes resistors 1812/1822 which may be implemented as similarly discussed with regard to resistors 1212/1222 of FIG. 12.

As shown, impedance circuit 1850 includes a single impedance element connected between input node 102 switch 1810, however additional impedance elements may be provided in other embodiments.

Circuit 1800 may be operated in a similar manner as circuit 1200 of FIG. 12, but with additional features and capabilities provided by impedance circuit 1850 (e.g., resistors or other appropriate circuit elements to dissipate a portion of RF signal 162). In addition, switch 1810 may be selectively operated before and after switch 1820 in response to various control signals as further discussed herein.

Although various specific impedance circuits 1650/1660/1750/1760/1850 are illustrated and described herein, other embodiments are also contemplated. For example, impedance elements may be added and/or omitted and with different connections as may be desired or appropriate for various implementations to protect ancillary switches 120/140.

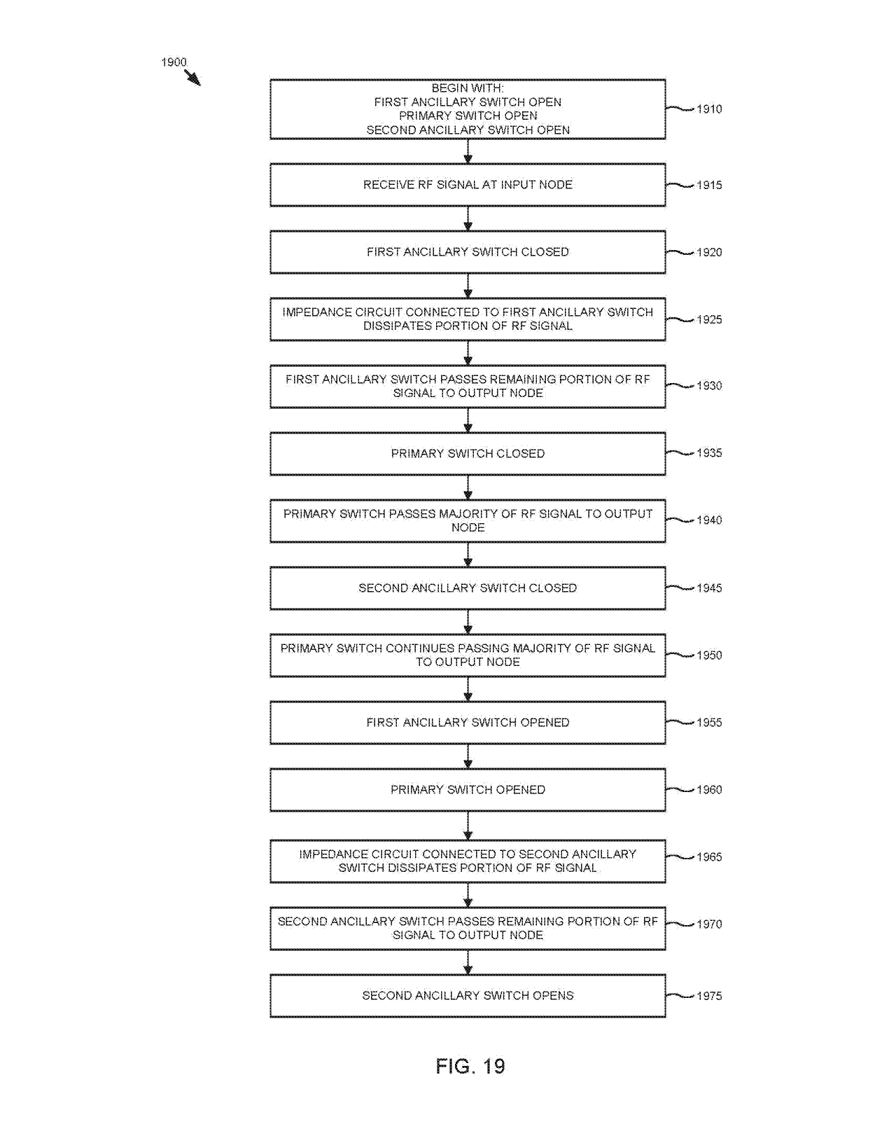

FIG. 19 illustrates a process 1900 of operating circuits 1600 and 1700 (e.g., each of which may be used to implement switching circuit 100) to protect switches 1610/1630 and 1710/1730 (e.g., each of which may be used to implement any of ancillary switches 120 and 140) using impedance circuits 1650/1660 and 1750/1760 in accordance with an embodiment of the disclosure. Although the blocks of FIG. 19 are illustrated in sequential order, various blocks may be performed simultaneously, in an overlapping manner, and/or in different orders as appropriate.

In block 1910, switches 1610/1710 (e.g., first ancillary switches), switches 1620/1720 (e.g., primary switches), and switches 1630/1730 (e.g., second ancillary switches) are in open states.

In block 1915, RF signal 162 is received at input node 102.

In block 1920, switches 1610/1710 are closed in response to control signals 172G/172H as received from control logic 170 and as delayed by the RC time constants associated with resistors 1612/1712 and the transistors of switches 1610/1710. As a result, input node 102 is connected to output node 104/105 through switches 1610/1710 and impedance circuits 1650/1750. In this regard, the closing of switches 1610/1710 (e.g., first ancillary switches) will reduce cross-coupled noise induced by the subsequent closing of switches 1620/1720 (e.g., primary switches).

In block 1925, impedance circuits 1650/1750 dissipate a first portion of RF signal 162. In block 1930, switches 1610/1710 pass a second portion (e.g., remaining portion) of RF signal 162 to output node 104/105. In some embodiments, blocks 1925 and 1930 may be performed simultaneously. As discussed, the dissipation performed by impedance circuits 1650/1750 prevents switches 1610/1710 from passing the entirety of RF signal 162 and thereby protects switches 1610/1710 during hot switching while RF signal 162 is present.

In block 1935, switches 1620/1720 are closed in response to control signals 172G/172H as received from control logic 170 and as delayed by the RC time constants associated with resistors 1622/1722 and the transistors of switches 1620/1720. As a result, input node 102 is further connected to output node 104/105 through switches 1620/1720. Accordingly, in block 1940, closed switches 1620/1720 pass a majority of RF signal 162 from input node 102 to output node 104/105. In some embodiments, closed switches 1610/1710 may continue to pass a portion of RF signal 162 while closed switches 1620/1720 pass the majority (or entirety) of RF signal 162. In some embodiments, switches 1610/1710 may be opened after switches 1620/1720 are closed (e.g., in response to other control signals).

In block 1945, switches 1630/1730 are closed in response to control signals 172G/172H as received from control logic 170 and as delayed by the RC time constants associated with resistors 1632/1732 and the transistors of switches 1640/1730. As a result, input node 102 is connected to output node 104/105 through switches 1630/1730 and impedance circuits 1660/1760. In this regard, the closing of switches 1630/1730 (e.g., second ancillary switches) will reduce cross-coupled noise induced by the subsequent opening of switches 1620/1720 (e.g., primary switches). In some embodiments, block 1945 may be performed simultaneously with block 1920 or block 1935 such that switches 1630/1730 are closed at the same time as switches 1610/1710 and/or 1620/1720.

In block 1950, switches 1620/1720 continue to pass the majority (or entirety) of RF signal 162 while all of switches 1610/1710, 1620/1720, and 1630/1730 remain closed.

In block 1955, switches 1610/1710 are opened in response to control signals 172G/172H as discussed.

In block 1960, switches 1620/1720 are opened in response to control signals 172G/172H as discussed.

In block 1965, impedance circuits 1660/1760 dissipate a first portion of RF signal 162. In block 1970, switches 1610/1710 pass a second portion (e.g., remaining portion) of RF signal 162 to output node 104/105. In some embodiments, blocks 1965 and 1970 may be performed simultaneously. As discussed, the dissipation performed by impedance circuits 1660/1760 prevents switches 1630/1730 from passing the entirety of RF signal 162 and thereby protects switches 1630/1730 during hot switching while RF signal 162 is present.

It will be appreciated that impedance circuits 1660/1760 may begin to dissipate portions of RF signal 162 earlier in block 1945 when switches 1630/1730 are closed. However, in some embodiments, significantly more dissipation may be performed in block 1965 after switches 1620/1720 are opened.

In block 1975, switches 1630/1730 are opened in response to control signals 172G/172H as discussed.

As discussed, in FIG. 16 and 17, control signals 172G and 172H are shared by switches 1610/1620/1630 and 1710/1720/1730, respectively. However, other embodiments are also contemplated. For example, additional control signals and associated control signal circuit paths may be provided to permit switches 1610/1710, 1620/1720, and 1630/1730 to operate independently. In such embodiments, switches 1610/1710 may be opened after switches 1620/1720 are closed. Also in such embodiments, switches 1630/1730 may remain open during the majority of the time that switches 1620/1720 are closed, and switches 1630/1730 may be closed immediately prior to the time that switches 1620/1720 are opened.

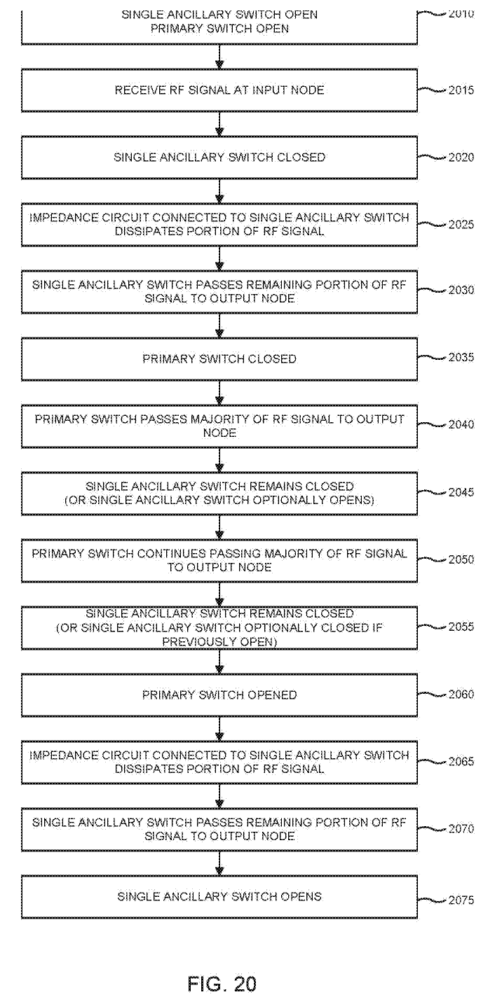

FIG. 20 illustrates a process 2000 of operating circuit 1800 (e.g., which may be used to implement switching circuit 100) to protect switch 1810 (e.g., which may be used to implement any of ancillary switches 120 and 140) using impedance circuit 1850 in accordance with an embodiment of the disclosure. Although the blocks of FIG. 20 are illustrated in sequential order, various blocks may be performed simultaneously, in an overlapping manner, and/or in different orders as appropriate.

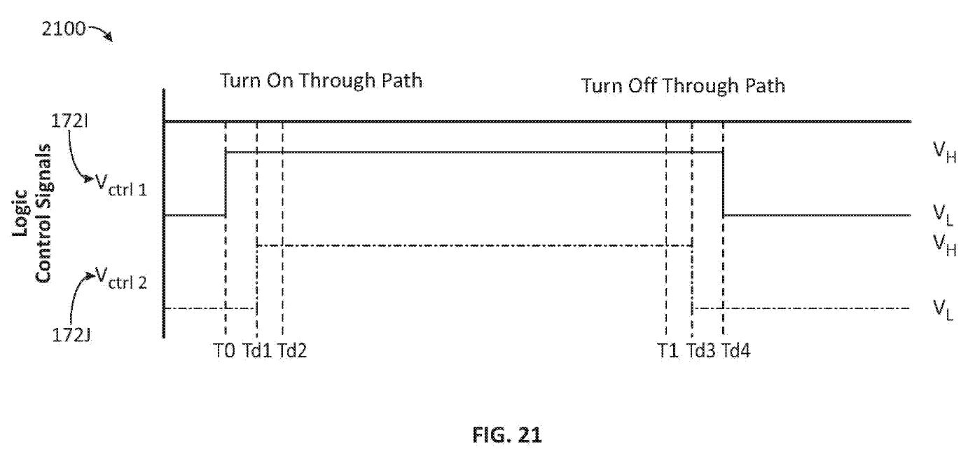

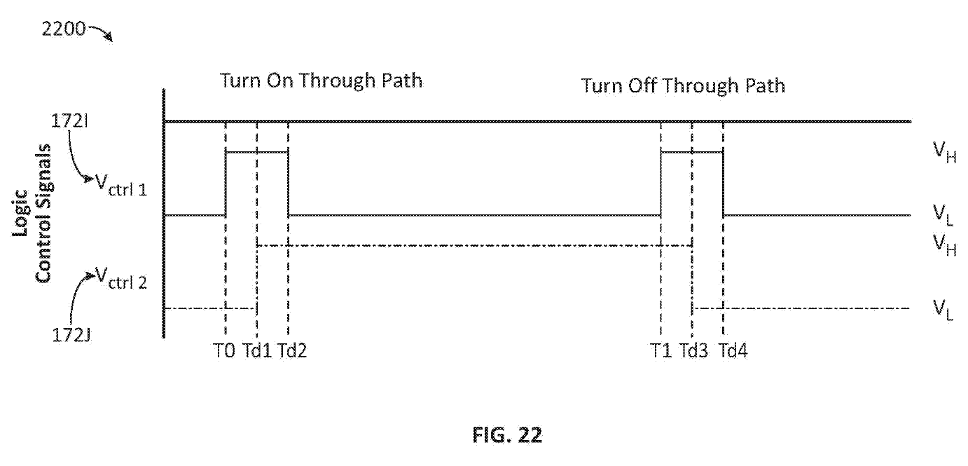

As shown in FIG. 20, switches 1810 and 1820 are receive separate control signals 172I and 172J which are delayed by the RC time constants associated with resistors 1812 and 1822 and the transistors of switches 1810/1820, respectively. Thus, it will be appreciated that switches 1810 and 1820 may be operated independently from each other in various embodiments. For example, FIGS. 21 and 22 illustrate timing diagrams 2100 and 2200 for control signals 172I and 172J. In particular, FIG. 21 illustrates an embodiment where switch 1810 remains closed while switch 1820 is closed. FIG. 22 illustrates an embodiment where switch 1810 temporarily opens while switch 1820 is closed. Further aspects of FIGS. 21 and 22 will be further discussed in relation to process 2000 of FIG. 20.

In block 2010, switch 1810 (e.g., ancillary switch) and switch 1820 (e.g., primary switch) are in open states. For example, as shown in FIGS. 21 and 22, control signals 172I and 172J are in logic low states prior to time T0 such that switches 1810 and 1820 are in open states.

In block 2015, RF signal 162 is received at input node 102.

In block 2020, switch 1810 is closed in response to control signal 172I. For example, as shown in FIGS. 21 and 22, control signal 172I transitions to a logic high state at time T0 such that switch 1810 is closed while switch 1820 remains open. As a result, input node 102 is connected to output node 104/105 through switch 1810 and impedance circuit 1850. In this regard, the closing of switch 1810 (e.g., ancillary switch) will reduce cross-coupled noise induced by the subsequent closing of switch 1820 (e.g., primary switch).

In block 2025, impedance circuit 1850 dissipates a first portion of RF signal 162. In block 2030, switch 1810 passes a second portion (e.g., remaining portion) of RF signal 162 to output node 104/105. In some embodiments, blocks 2025 and 2030 may be performed simultaneously. As discussed, the dissipation performed by impedance circuit 1850 prevents switch 1810 from passing the entirety of RF signal 162 and thereby protects switch 1810 during hot switching while RF signal 162 is present.

In block 2035, switch 1820 is closed in response to control signal 172J. For example, as shown in FIGS. 21 and 22, control signal 172J transitions to a logic high state at time Td1 such that both of switches 1810 and 1820 are now in closed states.

As a result, input node 102 is further connected to output node 104/105 through switch 1820. Accordingly, in block 2040, closed switch 1820 passes a majority of RF signal 162 from input node 102 to output node 104/105. In some embodiments, closed switch 1810 may continue to pass a portion of RF signal 162 while closed switch 1820 passes the majority (or entirety) of RF signal 162.

In block 2045, switch 1810 may remain closed after switch 1820 is closed in a first embodiment illustrated in FIG. 21, or may be opened after switch 1820 is closed in a second embodiment illustrated in FIG. 22. For example, in the first embodiment illustrated in FIG. 21, control signal 172I remains in a logic high state at time Td2 to keep switch 1810 closed while control signal 172J also remains in a logic high state at time Td2 to also keep switch 1820 closed. In the second embodiment illustrated in FIG. 22, control signal 172I transitions to a logic low state at time Td2 to open switch 1810 while control signal 172J remains in a logic high state at time Td2 to keep switch 1820 closed.

In block 2050, switch 1820 continues to pass the majority (or entirety) of RF signal 162 while switch 1810 remains in a closed state in the first embodiment or in an opened state in the second embodiment (e.g., depending on the operation of control signal 172I between time Td2 and time T1 as shown in FIGS. 21 and 22).

In block 2055, switch 1810 remains closed in the first embodiment, or transitions from an opened state to a closed state in the second embodiment. For example, in the first embodiment illustrated in FIG. 21, control signal 172I remains in a logic high state at time T1 to keep switch 1810 closed while control signal 172J also remains in a logic high state at time T1 to also keep switch 1820 closed. In the second embodiment illustrated in FIG. 22, control signal 172I transitions to a logic high state at time T1 to close switch 1810 while control signal 172J remains in a logic high state at time T1 to keep switch 1820 closed. In both the first and second embodiments, the closed state of switch 1810 (e.g., ancillary switch) at time T1 will reduce cross-coupled noise induced by the subsequent opening of switch 1820 (e.g., primary switch).

In block 2060, switch 1820 opens in response to control signal 172J. For example, ass illustrated in both FIGS. 21 and 22, control signal 172J transitions to a logic low state at time Td3 to open switch 1820 while control signal 172I remains in a logic high state at time Td3 to keep switch 1820 closed.

In block 2065, impedance circuit 1850 dissipates a first portion of RF signal 162. In block 2070, switch 1810 passes a second portion (e.g., remaining portion) of RF signal 162 to output node 104/105. In some embodiments, blocks 2065 and 2070 may be performed simultaneously. As discussed, the dissipation performed by impedance circuit 1850 prevents switch 1810 from passing the entirety of RF signal 162 and thereby protects switch 1810 during hot switching while RF signal 162 is present.

It will be appreciated that impedance circuit 1850 may dissipate portions of RF signal 162 from block 2025 to block 2065 during time periods where switches 1810 and 1820 are both closed. However, in some embodiments, significantly more dissipation may be performed while switch 1810 is closed and switch 1820 is opened.

In block 2075, switch 1810 opens in response to control signal 172I as discussed. For example, as shown in FIGS. 21 and 22, control signal 172I transitions to a logic low state at time Td4 such that switch 1810 opens while switch 1820 remains open.

Where applicable, various embodiments provided by the present disclosure can be implemented using hardware, software, or combinations of hardware and software. Also where applicable, the various hardware components and/or software components set forth herein can be combined into composite components comprising software, hardware, and/or both without departing from the spirit of the present disclosure. Where applicable, the various hardware components and/or software components set forth herein can be separated into sub-components comprising software, hardware, or both without departing from the spirit of the present disclosure. In addition, where applicable, it is contemplated that software components can be implemented as hardware components, and vice-versa.

Software in accordance with the present disclosure, such as program code and/or data, can be stored on one or more computer readable mediums. It is also contemplated that software identified herein can be implemented using one or more general purpose or specific purpose computers and/or computer systems, networked and/or otherwise. Where applicable, the ordering of various steps described herein can be changed, combined into composite steps, and/or separated into sub-steps to provide features described herein.

Embodiments described above illustrate but do not limit the invention. It should also be understood that numerous modifications and variations are possible in accordance with the principles of the present invention. Accordingly, the scope of the invention is defined only by the following claims.

What is claimed is:

1. A method comprising:
receiving an RF signal at an input node coupled to an output node through at least a primary switch, an impedance circuit, and an ancillary switch;
switching the ancillary switch from an open state to a closed state while the primary switch is in an open state;
dissipating a first portion of the RF signal by the impedance circuit while the ancillary switch is in the closed state;
passing a second portion of the RF signal by the ancillary switch in the closed state while the primary switch is in the open state;
switching the primary switch from the open state to a closed state; and
passing a majority RF signal by the primary switch in the closed state to the output node.

2. The method of claim 1, wherein:
the primary switch is sized to pass an entirety of the RF signal;
the ancillary switch is sized to pass only a reduced portion of the RF signal; and
the impedance circuit is configured to protect the ancillary switch from passing more than the reduced portion of the RF signal.

3. The method of claim 1, wherein the ancillary switch is a first ancillary switch, the method further comprising:
maintaining the first ancillary switch in the closed state for a time period after the primary switch switches to the closed state and/or switching the first ancillary switch from the closed state to the open state after the primary switch switches to the closed state;
switching a second ancillary switch from an open state to a closed state while the primary switch is in the closed state;
switching the primary switch from the closed state to the open state; and
maintaining the second ancillary switch in the closed state for another time period after the primary switch switches to the open state.

4. The method of claim 1, further comprising:
maintaining the ancillary switch in the closed state while the primary switch remains in the closed state and/or switching:
the ancillary switch from the closed state to the open state after the primary switch switches to the closed state, and
the ancillary switch from the open state to the closed state while the primary switch is in the closed state;
switching the primary switch from the closed state to the open state; and
maintaining the ancillary switch in the closed state for a time period after the primary switch switches to the open state.

5. The method of claim 1, wherein the impedance circuit comprises:
a first impedance element coupled between the input node and the ancillary switch; and
a second impedance element coupled between the ancillary switch and the output node.

6. The method of claim 1, wherein the ancillary switch comprises:
a first set of transistors connected in series between the input node and the output node; and
a second set of transistors connected in series between the input node and the output node, and connected in parallel with the first set of transistors.

7. The method of claim 6, wherein the impedance circuit comprises a first impedance element coupled between the input node and the first and second sets of transistors.

8. The method of claim 6, wherein the impedance circuit comprises a first impedance element coupled between the input node and the first set of transistors, and a second impedance element coupled between the input node and the second set of transistors.

9. The method of claim 1, wherein:
the ancillary switch is connected across the primary switch;
the ancillary switch reduces cross-coupled noise induced by the switching of the primary switch;
the primary switch is a primary shunt switch and/or a primary through switch; and
the ancillary switch is an ancillary shunt switch and/or an ancillary through switch.

10. The method of claim 1, wherein the method is performed by an antenna tuning switch.

11. A switching circuit comprising:
an input node configured to receive an RF signal;
an output node, wherein the input node is coupled to the output node through at least a primary switch, an ancillary switch, and an impedance circuit;
the impedance circuit configured to dissipate a first portion of the RF signal while the ancillary switch is in a closed state;
the ancillary switch configured to:
switch from an open state to the closed state while the primary switch remains in an open state, and
while in the closed state, pass a second portion of the RF signal while the primary switch is in an open state; and
the primary switch configured to:
switch from the open state to a closed state, and
while in the closed state, pass a majority of the RF signal to the output node.

12. The switching circuit of claim 11, wherein:
the primary switch is sized to pass an entirety of the RF signal;
the ancillary switch is sized to pass only a reduced portion of the RF signal; and
the impedance circuit is configured to protect the ancillary switch from passing more than the reduced portion of the RF signal.

13. The switching circuit of claim 11, wherein:
the ancillary switch is a first ancillary switch configured to maintain the closed state for a time period after the primary switch switches to the closed state and/or configured to switch from the closed state to the open state after the primary switch switches to the closed state;
the switching circuit further comprises a second ancillary switch configured to switch from an open state to a closed state while the primary switch is in the closed state;
the primary switch is configured to switch from the closed state to the open state; and
the second ancillary switch is configured to maintain the closed state for another time period after the primary switch switches to the open state.

14. The switching circuit of claim 11, wherein:
the ancillary switch is configured to maintain the closed state while the primary switch remains in the closed state and/or configured to:
switch from the closed state to the open state after the primary switch switches to the closed state, and
switch from the open state to the closed state while the primary switch is in the closed state;
the primary switch is configured to switch from the closed state to the open state; and
the ancillary switch is configured to maintain the closed state for a time period after the primary switch switches to the open state.

15. The switching circuit of claim 11, wherein the impedance circuit comprises:
a first impedance element coupled between the input node and the ancillary switch; and
a second impedance element coupled between the ancillary switch and the output node.

16. The switching circuit of claim 11, wherein the ancillary switch comprises:
a first set of transistors connected in series between the input node and the output node; and
a second set of transistors connected in series between the input node and the output node, and connected in parallel with the first set of transistors.

17. The switching circuit of claim 16, wherein the impedance circuit comprises a first impedance element coupled between the input node and the first and second sets of transistors.

18. The switching circuit of claim 16, wherein the impedance circuit comprises a first impedance element coupled between the input node and the first set of transistors, and a second impedance element coupled between the input node and the second set of transistors.

19. The switching circuit of claim 11, wherein:
the ancillary switch is connected across the primary switch;
the ancillary switch reduces cross-coupled noise induced by the switching of the primary switch;
the primary switch is a primary shunt switch and/or a primary through switch; and
the ancillary switch is an ancillary shunt switch and/or an ancillary through switch.

20. The switching circuit of claim 11, wherein the switching circuit is an antenna tuning switch.
